(19) United States
(12) Patent Application Publication
(10) Pub. No.: US 2026/0164907 A1
(43) Pub. Date: Jun. 11, 2026

(54) LIGHT SOURCE AND DISPLAY APPARATUS INCLUDING THE SAME

(71) Applicant: SAMSUNG ELECTRONICS CO., LTD., Suwon-si (KR)

(72) Inventors: Gyeongmi LEE, Suwon-si (KR); Junghwan KIL, Suwon-si (KR); Donggyu KIM, Suwon-si (KR); Joolee SON, Suwon-si (KR); Joonwoo JEON, Suwon-si (KR); Nara HWANG, Suwon-si (KR)

(73) Assignee: SAMSUNG ELECTRONICS CO., LTD., Suwon-si (KR)

(21) Appl. No.: 19/409,129

(22) Filed: Dec. 4, 2025

(30) Foreign Application Priority Data
Dec. 5, 2024 (KR) 10-2024-0179891

(51) Int. Cl. H10H 29/856; H10H 29/80

(52) U.S. Cl. CPC H10H 29/856; H10H 29/8325

(57) ABSTRACT

Provided is a light source including a first conductive type base semiconductor layer; a semiconductor light-emitting structure including a first conductive type semiconductor layer, an active layer, and a second conductive type semiconductor layer sequentially stacked in a vertical direction on a first surface of the first conductive type base semiconductor layer; a reflective structure configured to surround sidewalls of the semiconductor light-emitting structure and penetrate through at least a portion of the first conductive type base semiconductor layer; and a plurality of lenses arranged on a second surface of the first conductive type base semiconductor layer.

### CROSS-REFERENCE TO RELATED APPLICATION

This application is based on and claims priority under 35 U.S.C. § 119 to Korean Patent Application No. 10-2024-0179891, filed on Dec. 5, 2024, in the Korean Intellectual Property Office, the disclosure of which is incorporated herein in its entirety by reference.

### BACKGROUND

The disclosure relates to a light source and a display apparatus including the same, and more particularly, to a light source including a plurality of micro-light emitting diodes (micro-LEDs) and a display apparatus including the same.

An emission device, such as a light-emitting diode (LED), is a device in which a material contained therein emits light. LEDs are widely used as light sources for various display apparatuses such as lighting devices, televisions (TVs), mobile phones, personal computers (PCs), laptop computers, personal digital assistants (PDAs), digital cameras, camcorders, viewfinders, micro displays, three-dimensional (3D) displays, virtual reality or augmented reality displays, etc. Recently, micro-or nano-scale ultra-small LEDs using II-VI group or III-V group compound semiconductors are being developed. There is an increasing need for LEDs to achieve uniform light emission.

### SUMMARY

The disclosure provides a light source having a structure capable of improving light extraction efficiency.

The disclosure also provides a display apparatus including a light source having a structure capable of improving light extraction efficiency.

According to an aspect of an example embodiment of the disclosure, there is provided a light source including: a first conductive type base semiconductor layer; a semiconductor light-emitting structure on a first surface of the first conductive type base semiconductor layer, the semiconductor light-emitting structure including a first conductive type semiconductor layer, an active layer, and a second conductive type semiconductor layer sequentially stacked in a vertical direction; a reflective structure configured to surround sidewalls of the semiconductor light-emitting structure and penetrate through at least a portion of the first conductive type base semiconductor layer; and a plurality of lenses arranged on a second surface of the first conductive type base semiconductor layer.

According to an aspect of an example embodiment of the disclosure, there is provided a light source including: a plurality of pixels, at least one pixel of which includes a first conductive type base semiconductor layer and a semiconductor light-emitting structure on a first surface of the first conductive type base semiconductor layer, the semiconductor light-emitting structure including a first conductive type semiconductor layer, an active layer, and a second conductive type semiconductor layer sequentially stacked in a vertical direction; a plurality of transparent electrode layers configured to cover second conductive type semiconductor layers, respectively and spaced vertically from active layers with the second conductive type semiconductor layers therebetween; a plurality of reflective electrode layers in contact with the plurality of transparent electrode layers and spaced apart in the vertical direction from the second conductive type semiconductor layers with the plurality of transparent electrode layers therebetween, respectively; and a reflective structure configured to surround sidewalls of the semiconductor light-emitting structure and have at least a portion overlapping the first conductive type base semiconductor layer in a horizontal direction, wherein the reflective structure includes a first portion extending in the horizontal direction and a second portion having an inclination and extending in the vertical direction from an end portion of the first portion.

According to an aspect of an example embodiment of the disclosure, there is provided a display apparatus including: a circuit board including a driving circuit; a pixel array including a plurality of pixels arranged on the circuit board and including semiconductor light-emitting structures; a plurality of lenses respectively disposed over the plurality of pixels, and a reflective structure configured to surround each of the plurality of pixels and contact at least a portion of the plurality of lenses, wherein at least one pixel of the plurality of pixels includes a first conductive type base semiconductor layer and a semiconductor light-emitting structure, the semiconductor light-emitting structure including a first conductive type semiconductor layer, an active layer, and a second conductive type semiconductor layer sequentially stacked in a vertical direction, the semiconductor light-emitting structure is spaced apart from one lens selected from among the plurality of lenses with the first conductive type base semiconductor layer therebetween, and the reflective structure includes a first portion extending in a horizontal direction and a second portion having an inclination and extending in a vertical direction from an end portion of the first portion.

According to an aspect of an aspect of an example embodiment of the disclosure, there is provided a method of manufacturing a display apparatus including a light source, the light source including a pixel region in which a plurality of pixels are disposed, the method including: forming, on a growth substrate, a first conductive type base semiconductor layer and a plurality of semiconductor light-emitting structures on a first surface of the first conductive type base semiconductor layer in the pixel region, at least one semiconductor light-emitting structure including a first conductive type semiconductor layer, an active layer, and a second conductive type semiconductor layer; forming a plurality of transparent electrode layers covering the plurality of semiconductor light-emitting structures; forming a plurality of insulation spacers covering sidewalls of the plurality of semiconductor light-emitting structures and sidewalls and top surfaces of the plurality of transparent electrode layers; forming trenches between the plurality of semiconductor light-emitting structures; forming a reflective structure covering the plurality of insulation spacers and the trenches; forming an opening of the reflective structure that opens a region overlapping a semiconductor light-emitting structure, and forming a plurality of contact holes overlapping the opening; etching a portion of each of the plurality of transparent electrode layers exposed through the plurality of contact holes; and forming a plurality of lenses on a second surface of the first conductive type base semiconductor layer.

The method may further include forming, on a circuit board, a first bonding insulation layer on a first insulation layer, and a plurality of first bonding electrodes penetrating through the first bonding insulation layer and connected to a plurality of wiring lines.

The method may further include forming a plurality of reflective electrode layers on an exposed surface of the plurality of transparent electrode layers; forming a plurality of second bonding electrodes connected to the plurality of reflective electrode layers; and forming a second bonding insulation layer surrounding the plurality of second bonding electrodes.

The first bonding insulation layer may be bonded to the second bonding insulation layer through a dielectric-dielectric bonding.

The plurality of first bonding electrodes may be bonded to the plurality of second bonding electrodes through copper (Cu)-copper (Cu) bonding.

The forming the plurality of lenses may include removing the growth substrate to expose the first conductive type base semiconductor layer; and forming the plurality of lenses on the second surface of the first conductive type base semiconductor layer.

### BRIEF DESCRIPTION OF THE DRAWINGS

Embodiments of the disclosure will be more clearly understood from the following detailed description taken in conjunction with the accompanying diagrams in which:

FIG. 1 is a plan view illustrating a light source according to embodiments;

FIGS. 2 to 6 are cross-sectional views illustrating light sources according to embodiments, respectively;

FIG. 7A is a schematic perspective view illustrating a light source according to embodiments;

FIG. 7B is a schematic plan view of ta semiconductor light-emitting structure shown in FIG. 7A;

FIG. 8A is a schematic perspective view illustrating a light source, according to other embodiments;

FIG. 8B is a schematic plan view of a semiconductor light-emitting structure shown in FIG. 8A;

FIGS. 8C and 8D are plan views for describing light sources according to other embodiments, respectively;

FIG. 9 is a schematic perspective view of a display apparatus according to embodiments;

FIG. 10 is an enlarged plan view of a portion EX2 in FIG. 9;

FIGS. 11 to 14 are schematic cross-sectional views illustrating components of a portion taken along a line I-I′ of FIG. 9 and a portion taken along a line II-II′ of FIG. 10, respectively;

FIGS. 15A to 15F are cross-sectional views for describing a method of manufacturing a display apparatus including a light source according to a process sequence, according to embodiments;

FIG. 16 is a block diagram an electronic device including a light source or a display apparatus, according to embodiments; and

FIGS. 17 to 21 are diagrams illustrating electronic devices including a light source or a display apparatus according to embodiments, respectively.

### DETAILED DESCRIPTION

Hereinafter, the disclosure will be described more fully with reference to the accompanying drawings, in which embodiments of the disclosure are shown. In the drawings, like elements are denoted by like reference numerals, and a repeated explanation thereof will not be given. In addition, one of ordinary skill would understand that aspects of some embodiments may be combined together or implemented alone.

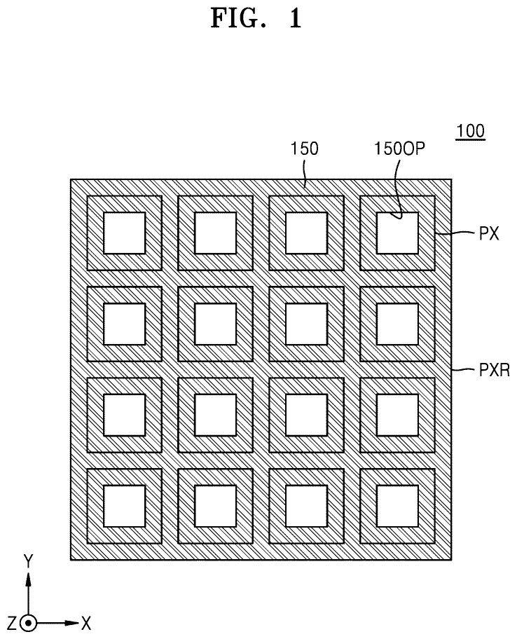

FIG. 1 is a plan view illustrating a light source 100 according to embodiments.

Referring to FIG. 1, the light source 100 includes a pixel region PXR in which a plurality of pixels PX are disposed. The plurality of pixels PX may be configured to emit light of a particular wavelength, e.g., light of a particular color. According to embodiments, the plurality of pixels PX may be configured to emit the same color. According to embodiments, the plurality of pixels PX may each be configured to emit light of the same color selected from among red (R) light, green (G) light, and blue (B) light. According to other embodiments, some of the plurality of pixels PX may be configured to emit red light, some other pixels PX may be configured to emit green light, and still some other pixels PX may be configured to emit blue light. According to still other embodiments, some other pixels PX may be configured to emit light of a color other than red, green, and blue, e.g., yellow light. In the pixel region PXR of FIG. 1, the plurality of pixels PX are illustrated in a form of a 4×4 pixel array in which pixels PX are arranged in a first horizontal direction (X direction) and a second horizontal direction (Y direction), but the disclosure is not limited thereto. In the pixel region PXR, the plurality of pixels PX may include any suitable number of pixels PX arranged in the first horizontal direction (X direction) and the second horizontal direction (Y direction), e.g., the plurality of pixels PX having an arrangement of 1,024×768. The light source 100 may further include a reflective structure 150 and openings 150OP, which will be described in detail later.

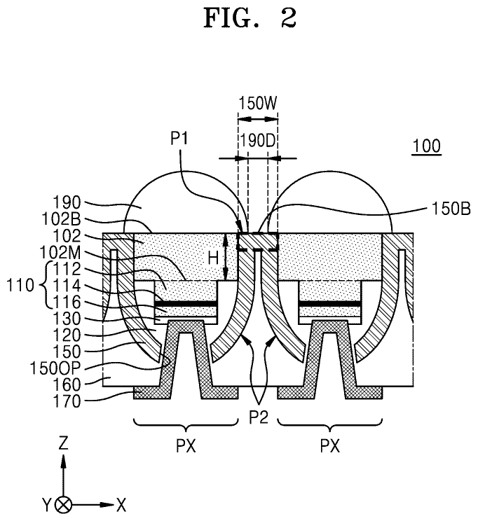

FIGS. 2 to 6 are cross-sectional views illustrating light sources 100, 100A, 100B, 100C, and 100D according to embodiments, respectively. The light sources 100, 100A, 100B, 100C, and 100D may have the same planar structure as a planar structure of the light source 100 shown in FIG. 1. In FIGS. 2 to 6, the same reference numerals denote the same elements, and redundant descriptions thereof are omitted.

Referring to FIG. 2, a pixel PX may include a first conductive type base semiconductor layer 102 and a semiconductor light-emitting structure 110 disposed on a main surface 102M of the first conductive type base semiconductor layer 102. The semiconductor light-emitting structure 110 may include a first conductive type semiconductor layer 112, an active layer 114, and a second conductive type semiconductor layer 116 sequentially stacked in a vertical direction (Z direction) with respect to the main surface 102M of the first conductive type base semiconductor layer 102.

The semiconductor light-emitting structure 110 may include a micro-LED. According to embodiments, the semiconductor light-emitting structure 110 may include a micro-LED that emits light of any one color selected from red, green, and blue. The term “micro-LED” as used herein may mean an LED having a width of about 100 μm or less in a horizontal direction (e.g., X direction) perpendicular to the vertical direction (Z direction). For example, a width of the semiconductor light-emitting structure 110 in the horizontal direction (e.g., X direction) may be about 100 μm or less, about 50 μm or less, about 20 μm or less, about 10 μm or less, about 6 μm or less, about 5 μm or less, about 4 μm or less, or about 2 μm or less, but is not limited thereto.

The semiconductor light-emitting structure 110 may be configured to emit light having a wavelength λ selected within a range from about 400 nm to about 700 nm.

According to embodiments, the semiconductor light-emitting structure 110 may be configured to emit light of a first wavelength selected within a range from about 580 nm to about 700 nm. Light of the first wavelength may be red light. In this specification, the wavelength range of the red light may mean a wavelength range from about 580 nm to about 700 nm, e.g., a wavelength range from about 610 nm to about 650 nm or a wavelength range from about 620 nm to about 640 nm, and may have at least one peak of an emission spectrum in the wavelength range of the red light.

According to other embodiments, the semiconductor light-emitting structure 110 may be configured to emit light of a second wavelength selected within a range from about 490 nm to about 580 nm. Light of the second wavelength may be green light. In this specification, the wavelength range of the green light may mean a wavelength range from about 490 nm to about 580 nm, e.g., a wavelength range from about 510 nm to about 550 nm or a wavelength range from about 520 nm to about 540 nm, and may have at least one peak of an emission spectrum in the wavelength range of the green light.

According to still other embodiments, the semiconductor light-emitting structure 110 may be configured to emit light of a third wavelength selected within a range from about 400 nm to about 490 nm. Light of the third wavelength may be blue light. In this specification, the wavelength range of the blue light may mean a wavelength range from about 400 nm to about 490 nm, e.g., a wavelength range from about 440 nm to about 480 nm or a wavelength range from about 450 nm to about 470 nm, and may have at least one peak of an emission spectrum in the wavelength range of the blue light.

The first conductive type base semiconductor layer 102, the first conductive type semiconductor layer 112, the active layer 114, and the second conductive type semiconductor layer 116 may each include an epitaxial nitride semiconductor layer. The first conductive type base semiconductor layer 102 and the first conductive type semiconductor layer 112 may include nitride semiconductor layers doped with dopants of the same conductive type, e.g., n-type dopants, and an average doping concentration of the first conductive type base semiconductor layer 102 may be higher than an average doping concentration of the first conductive type semiconductor layer 112. The first conductive type semiconductor layer 112 and the second conductive type semiconductor layer 116 may each be formed as a single layer or may each be formed as a multi-layer including a plurality of layers having different dopant doping concentrations, different compositions of constituents, etc. The first conductive type base semiconductor layer 102 may be spaced apart from the active layer 114 in the vertical direction (Z direction) with the first conductive type semiconductor layer 112 therebetween.

The first conductive type base semiconductor layer 102 may have a thickness from about 10 nm to about 6,000 nm in the vertical direction (Z direction). The first conductive type semiconductor layer 112 may have a thickness from about 10 nm to about 500 nm in the vertical direction (Z direction).

In the semiconductor light-emitting structure 110, the first conductive type semiconductor layer 112 may have a structure integrally connected to the first conductive type base semiconductor layer 102. According to embodiments, the first conductive type base semiconductor layer 102 and the first conductive type semiconductor layer 112 may include the same material. According to embodiments, the first conductive type base semiconductor layer 102 may include n-type gallium nitride (n-GaN). The first conductive type semiconductor layer 112 may include an n-type superlattice structure layer. For example, the first conductive type semiconductor layer 112 may include an InGaN/GaN superlattice structure layer. In this case, the first conductive type semiconductor layer 112 may have a superlattice structure in which InGaN films and GaN films are alternately stacked one-by-one. In the first conductive type semiconductor layer 112, the superlattice structure may include pair structures of an InGaN film and a GaN film from about 10 periods to about 50 periods, e.g., from about 15 to about 20 periods, but is not limited thereto.

According to other embodiments, the first conductive type semiconductor layer 112 may include a nitride semiconductor layer having a composition of InₓAl_{y}Ga_{1-x-y}N (0≤x<1, 0≤y<1, 0≤x+y<1). According to still other embodiments, the first conductive type semiconductor layer 112 may include n-type gallium nitride (n-GaN) doped with silicon (Si), germanium (Ge), or carbon (C). According to still other example embodiments, the first conductive type semiconductor layer 112 may include a semiconductor layer of aluminum indium gallium phosphide (AlInGaP) or aluminum indium gallium arsenide (AlInGaAs).

In the semiconductor light-emitting structure 110, the active layer 114 may be configured to emit light having a certain energy due to re-combination of electrons and holes. The active layer 114 may have a single quantum well or a multiple quantum well structure in which quantum barrier layers and quantum well layers are alternately arranged. According to embodiments, the active layer 114 may have a single or a plurality of quantum well structures including one pair structure including one quantum barrier layer and one quantum well layer for 1 to 15 periods.

According to embodiments, the active layer 114 may include a quantum barrier layer and a quantum well layer including compound semiconductors of group III-V elements. For example, the active layer 114 may include any one of a pair structure selected from among InGaN/GaN, InGaN/InGaN, InGaN/AlGaN, and InGaN/InAlGaN, but is not limited thereto.

According to embodiments, the quantum well layer and the quantum barrier layer may include InₓAl_{y}Ga_{1-x-y}N (0≤x≤1, 0≤y≤1, 0≤x+y≤1) layers having different compositions. For example, the quantum well layer may include an undoped InₓGa₁₋ₓN (0<x<1) layer, and the quantum barrier layer may include an undoped GaN layer or a GaN layer doped with silicon (Si).

According to embodiments, when the quantum well layer included in the active layer 114 is an InₓGa₁₋ₓN (0<x<1) layer, bandgap energy in the active layer 114 may be controlled according to a content ratio of indium (In) in the quantum well layer to adjust a light-emission wavelength band. When the quantum well layer included in the active layer 114 is an InₓGa₁₋ₓN (0<x<1) layer, an x value indicating an indium (In) content ratio in the quantum well layer may be selected within a range from about 0.15 to about 0.35. For example, when the semiconductor light-emitting structure 110 is configured to emit red light, the x value in the InₓGa₁₋ₓN (0<x<1) layer constituting the quantum well layer contained in the active layer 114 may be selected within a range from about 0.3 to about 0.35. When the semiconductor light-emitting structure 110 is configured to emit green light, the x value in the InₓGa₁₋ₓN (0<x<1) layer constituting the quantum well layer contained in the active layer 114 may be selected within a range from about 0.25 to about 0.3. When the semiconductor light-emitting structure 110 is configured to emit blue light, the x value in the InₓGa₁₋ₓN (0<x<1) layer constituting the quantum well layer contained in the active layer 114 may be selected within a range from about 0.15 to about 0.2. However, the disclosure is not limited thereto.

In the vertical direction (Z direction), the thickness of the active layer 114 may be less than about 300 nm. The active layer 114 has a surface in contact with the first conductive type semiconductor layer 112 and a surface in contact with the second conductive type semiconductor layer 116, and a shortest distance from the surface of the active layer 114 in contact with the first conductive type semiconductor layer 112 to the surface of the active layer 114 in contact with the second conductive type semiconductor layer 116 may be less than about 300 nm.

According to embodiments, the active layer 114 may include a multi-quantum well layer having a pair structure including one quantum barrier layer and one quantum well layer from 8 periods to 12 periods, the multi-quantum well layer may have a surface in contact with the first conductive type semiconductor layer 112 and a surface in contact with the second conductive type semiconductor layer 116, and the multi-quantum well layer may have a thickness of less than about 300 nm in the vertical direction (Z direction).

According to embodiments, the active layer 114 may have a thickness of less than about 300 nm, less than about 200 nm, less than about 100 nm, less than about 50 nm, less than about 40 nm, less than about 20 nm, less than about 10 nm, less than about 5 nm, or less than about 3 nm. For example, the thickness of the active layer 114 may be selected within a range from about 2 nm to about 10 nm, but is not limited thereto.

According to embodiments, the thickness of the active layer 114 in the vertical direction (Z direction) may be determined according to the wavelength λ of light emitted from the semiconductor light-emitting structure 110, and, in this case, the thickness of the active layer 114 in the vertical direction (Z direction) may be less than 0.4 λ. For example, when the semiconductor light-emitting structure 110 is configured to emit red light of a first wavelength λ1 selected within a range from about 580 nm to about 700 nm, the thickness of the active layer 114 in the vertical direction (Z direction) may be less than 0.4 λ1 . In another example, when the semiconductor light-emitting structure 110 is configured to emit green light of a second wavelength λ2 selected within a range from about 490 nm to about 580 nm, the thickness of the active layer 114 in the vertical direction (Z direction) may be less than 0.4 λ2 . In still another example, when the semiconductor light-emitting structure 110 is configured to emit blue light of a third wavelength λ3 selected within a range of about 400 nm to about 490 nm, the thickness of the active layer 114 in the vertical direction (Z direction) may be less than 0.4 λ3 .

In the semiconductor light-emitting structure 110, the second conductive type semiconductor layer 116 may include a nitride semiconductor layer doped with a p-type dopant. According to embodiments, the second conductive type semiconductor layer 116 may include a nitride semiconductor layer having a composition of InₓAl_{y}Ga_{1-x-y}N (0≤x<1, 0≤y<1, 0≤x+y<1). For example, the second conductive type semiconductor layer 116 may include p-type gallium nitride (p-GaN) doped with magnesium (Mg) or zinc (Zn). However, the disclosure is not limited thereto. According to other embodiments, the second conductive type semiconductor layer 116 may include a semiconductor layer of aluminum indium gallium phosphide (AlInGaP) or aluminum indium gallium arsenide (AlInGaAs).

In the light source 100, the second conductive type semiconductor layer 116 of each of the plurality of pixels PX may be covered with a transparent electrode layer 130. The transparent electrode layer 130 may be spaced apart from the active layer 114 in the vertical direction (Z direction) with the second conductive type semiconductor layer 116 therebetween.

Sidewalls of the first conductive type semiconductor layer 112, the active layer 114, and the second conductive type semiconductor layer 116 included in the semiconductor light-emitting structure 110 and sidewalls of the transparent electrode layer 130 may be covered with a reflective structure 150. In other words, the reflective structure 150 may surround sidewalls of the semiconductor light-emitting structure 110 and the transparent electrode layer 130. Referring to FIGS. 1 and 2, the semiconductor light-emitting structure 110 and the transparent electrode layer 130 may be surrounded by the reflective structure 150 when viewed in a planar (an X-Y plane) perspective. The reflective structure 150 may control light distribution by reflecting light traveling from an inside of the semiconductor light-emitting structure 110 toward the sidewalls of the semiconductor light-emitting structure 110.

The reflective structure 150 may penetrate through at least a portion of the first conductive type base semiconductor layer 102. At least the portion of the first conductive type base semiconductor layer 102 may be a region between semiconductor light-emitting structures 110 adjacent to each other or a region between pixels PX adjacent to each other. A back surface 150B of a first portion P1 of the reflective structure 150 may be coplanar with the back surface of the first conductive type base semiconductor layer 102. At least a portion of the reflective structure 150 may overlap the first conductive type base semiconductor layer 102 in the horizontal direction (a direction on the X-Y plane). A thickness H of the first conductive type base semiconductor layer 102 may be 300 nm or greater.

The reflective structure 150 may include the first portion P1 and a second portion P2. The first portion P1 may extend parallel to the horizontal direction (a direction on the X-Y plane), and the second portion P2 may extend in the vertical direction (the Z direction; more particularly, a (−)Z direction) from an end portion of the first portion P1. The second portion P2 may be sloped (or have an inclination) with respect to the vertical direction (Z direction) and may extend in the vertical direction (Z direction).

Referring to FIG. 2, according to an embodiment, the first portion P1 may overlap the first conductive type base semiconductor layer 102 in the horizontal direction (a direction on the X-Y plane). A portion of the second portion P2 adjacent to the first portion P1 may overlap the first conductive type base semiconductor layer 102 in the horizontal direction (a direction on the X-Y plane), and a remaining portion of the second portion P2 may not overlap the first conductive type base semiconductor layer 102 in the horizontal direction (a direction on the X-Y plane).

According to embodiments, the reflective structure 150 may include, for example but not limited to, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), titanium (Ti), titanium nitride (TiN), tantalum (Ta), tantalum nitride (TaN), tungsten (W), or any combination thereof. For example, the reflective structure 150 may have a multi-layered structure including a TiN film, an Al film, and a Ti film sequentially stacked on a sidewall of the semiconductor light-emitting structure 110, but is not limited thereto. According to other embodiments, the reflective structure 150 may include a distributed Bragg reflector (DBR).

The light source 100 according to various embodiments may include the reflective structure 150 penetrating through the first conductive type base semiconductor layer 102 around the semiconductor light-emitting structure 110, thereby preventing light L emitted by the semiconductor light-emitting structure 110 of one pixel PX from leaking to the adjacent pixel PX and improving light efficiency.

The transparent electrode layer 130 may be in contact with the second conductive type semiconductor layer 116 and may be spaced apart from the active layer 114 in the vertical direction (Z direction) with the second conductive type semiconductor layer 116 therebetween. The second conductive type semiconductor layer 116 has a surface in contact with the active layer 114 and a surface in contact with the transparent electrode layer 130, and the surface in contact with the active layer 114 and the surface in contact with the transparent electrode layer 130 of the second conductive type semiconductor layer 116 may be surfaces opposite to each other in the vertical direction (Z direction).

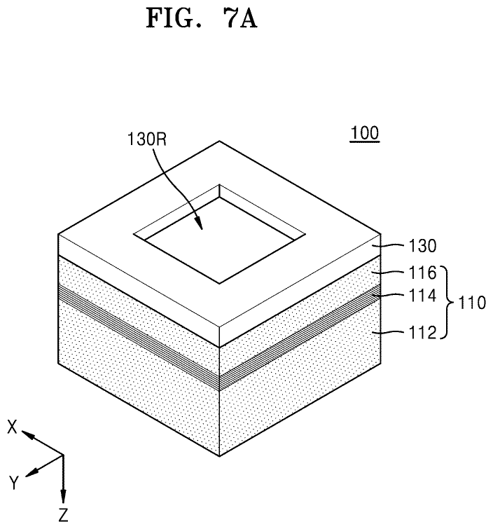

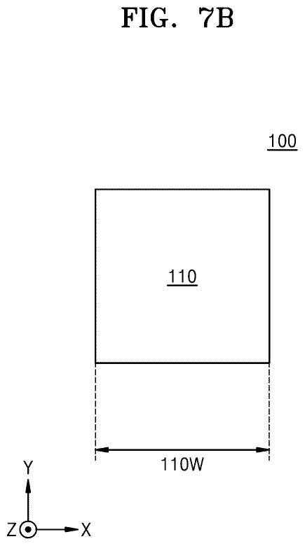

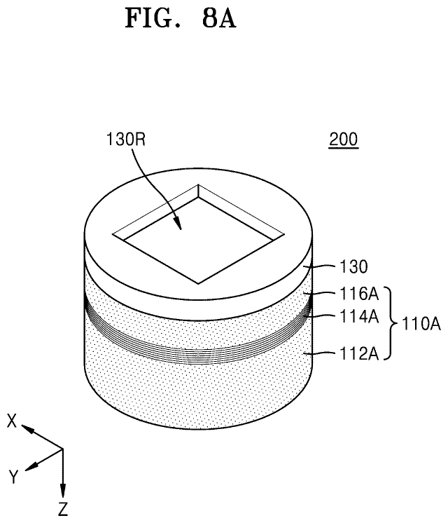

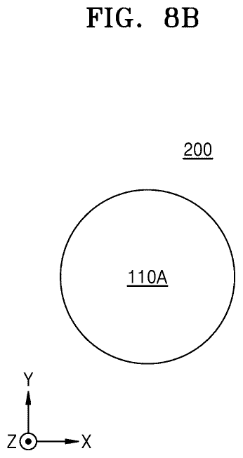

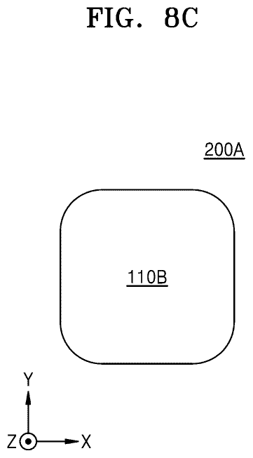

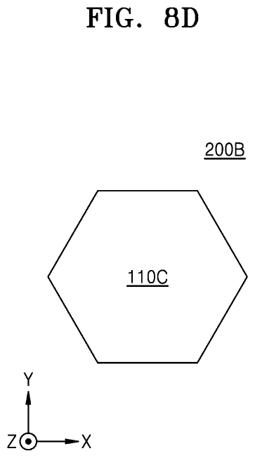

A reflective electrode layer 170 may be disposed on the transparent electrode layer 130. The reflective electrode layer 170 may be in contact with the transparent electrode layer 130 and spaced apart in the vertical direction (Z direction) from the second conductive type semiconductor layer 116 with the transparent electrode layer 130 therebetween. As described below with reference to FIGS. 7A and 8A, a local recess 130R may be formed in a surface of the transparent electrode layer 130 facing the reflective electrode layer 170. A portion of the reflective electrode layer 170 may be accommodated in the local recess 130R of the transparent electrode layer 130. FIG. 2 illustrates a structure in which the width of a portion of the reflective electrode layer 170 that contacts the transparent electrode layer 130 in the horizontal direction (e.g., X direction) is less than the width of the semiconductor light-emitting structure 110. However, the disclosure is not limited thereto. For example, the width of the portion of the reflective electrode layer 170 that contacts the transparent electrode layer 130 in the horizontal direction (e.g., X direction) may be equal to or greater than the width of the semiconductor light-emitting structure 110.

The reflective electrode layer 170 may include, for example but not limited to, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), titanium (Ti), titanium nitride (TiN), tantalum (Ta), tantalum nitride (TaN), tungsten (W), or any combination thereof. For example, the reflective electrode layer 170 may have a multi-layered structure in which a TiN film, an Al film, and a Ti film are sequentially stacked, but is not limited thereto. The reflective electrode layer 170 may be spaced apart from the reflective structure 150. An insulation spacer may be provided between the reflective electrode layer 170 and the reflective structure 150. The insulation spacer may include a silicon oxide, but is not limited thereto.

The semiconductor light-emitting structure 110 may have a columnar shape having a central axis extending in the vertical direction (Z direction). The semiconductor light-emitting structure 110 may have a width of less than 100 μm in a first direction (e.g., X direction) orthogonal to the vertical direction (Z direction). According to embodiments, the width of the semiconductor light-emitting structure 110 in the first direction (e.g., the X direction) may be from about 100 nm to about 10 μm, or from about 500 nm to about 1500 nm.

The transparent electrode layer 130 may have a width that is equal or similar to the width of the semiconductor light-emitting structure 110 in the first direction (e.g., X direction). In the vertical direction (Z direction), the transparent electrode layer 130 may have a variable thickness. A portion of the transparent electrode layer 130 that contacts the reflective electrode layer 170 may have a smaller thickness in the vertical direction (Z direction) than other portions of the transparent electrode layer 130. According to embodiments, a maximum thickness of the transparent electrode layer 130 in the vertical direction (Z direction) may be from about 50 nm to about 150 nm, and the portion of the transparent electrode layer 130 that contacts the reflective electrode layer 170 may have a thickness from about 30 nm to about 70 nm, but the disclosure is not limited thereto.

The transparent electrode layer 130 may include a transparent conductive material. According to embodiments, the transparent electrode layer 130 may include, for example but not limited to, Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTO), Aluminum-doped Zinc Oxide (AZO), Gallium-doped Zinc Oxide (GZO), In₄Sn₃O₁₂, Zinc Magnesium Oxide (Zn(1−x)MgxO, 0≤x≤1), or any combination thereof.

From a planar perspective (X-Y plane), the semiconductor light-emitting structure 110 may have various planar shapes. For example, the semiconductor light-emitting structure 110 may have a planar shape of a circle, an ellipse, or a polygon. The polygon may be, but is not limited to, a square, a hexagon, or an octagon. From the planar perspective (X-Y plane of FIG. 1), a planar shape of the transparent electrode layer 130 may be identical or similar to the planar shape of the semiconductor light-emitting structure 110. The semiconductor light-emitting structure 110 and the transparent electrode layer 130 may form a single pillar-like shape. Detailed examples of the planar shape of the semiconductor light-emitting structure 110 will be described later with reference to FIGS. 7A, 7B, and 8A to 8D.

Referring to FIG. 2, the light source 100 may include an insulation spacer 120 covering the semiconductor light-emitting structure 110. The insulation spacer 120 may cover sidewalls of the semiconductor light-emitting structure 110. The insulation spacer 120 may be placed between the semiconductor light-emitting structure 110 and the reflective structure 150. The insulation spacer 120 may be surrounded by at least a portion of the main surface 102M of the first conductive type base semiconductor layer 102, a side surface of the semiconductor light-emitting structure 110, a side surface of the transparent electrode layer 130, at least a portion of a top surface of the transparent electrode layer 130, at least a portion of a side surface of the reflective electrode layer 170, and at least a portion of a side surface of the reflective structure 150.

According to an embodiment, the insulation spacer 120 may include, for example but not limited to, tetraethyl ortho silicate (TEOS), undoped silicate glass (USG), phosphosilicate glass (PSG), borosilicate glass (BSG), borophosphosilicate glass (BPSG), fluoride silicate glass (FSG), spin on glass (SOG), polysilazane, or any combination thereof.

The light source 100 may include an insulation layer 160 covering the reflective structure 150. The insulation layer 160 may be buried (or embedded) in a region surrounded by the first portion P1 and the second portion P2 of the above-stated reflective structure 150. The reflective electrode layer 170 may cover a portion of the insulation layer 160 and may penetrate through the reflective structure 150 in the vertical direction (Z direction) to contact the transparent electrode layer 130. The reflective electrode layer 170 may be placed in an opening 150OP of the reflective structure 150.

According to an embodiment, the insulation layer 160 may include, for example but not limited to, tetraethyl ortho silicate (TEOS), undoped silicate glass (USG), phosphosilicate glass (PSG), borosilicate glass (BSG), borophosphosilicate glass (BPSG), fluoride silicate glass (FSG), spin on glass (SOG), polysilazane, or any combination thereof.

The light source 100 may further include a plurality of lenses 190. In this specification, a lens 190 may also be referred to as a micro-lens. The plurality of lenses 190 may be respectively arranged on first conductive type base semiconductor layers 102 of the plurality of pixels PX. Each of the plurality of lenses 190 may be spaced apart in the vertical direction (Z direction) from the semiconductor light-emitting structure 110 with the first conductive type base semiconductor layer 102 therebetween.

The plurality of lenses 190 may be configured to extract light emitted from the semiconductor light-emitting structure 110. In each of the plurality of pixels PX, the first conductive type base semiconductor layer 102 may have the main surface 102M that is in contact with the first conductive type semiconductor layer 112 and a back surface 102B that is an opposite surface of the main surface 102M, and the plurality of lenses 190 may be in contact with a light-emitting surface that is a portion of the back surface 102B of the first conductive type base semiconductor layer 102. The plurality of lenses 190 may each be disposed to overlap the semiconductor light-emitting structure 110 in the vertical direction (Z direction). According to embodiments, the plurality of lenses 190 may each include a spherical micro-lens or an aspherical micro-lens. According to embodiments, the plurality of lenses 190 may each include a graded-refractive index layer having a multi-layered structure in which a refractive index gradually decreases in a direction of light propagation. The graded-refractive index layer may be formed by using an oblique deposition method, a sputtering, an evaporation method, etc. The graded-refractive index layer may be configured such that the refractive index gradually decreases in a direction toward a light emission surface. According to embodiments, the plurality of lenses 190 may include TiO₂, SiC, GaN, GaP, SiN, SiON, ZrO₂, ITO, AlN, Al₂O₃, MgO, SiO₂, CaF₂, MgF₂, or any combination thereof. According to other embodiments, the plurality of lenses 190 may include a transparent resin. For example, the plurality of lenses 190 may include an acrylic resin series such as polymethyl methacrylate (PMMA), polyethylene terephthalate (PET), poly carbonate (PC), cycloolefin copolymer (COC), polyethylene naphthalate (PEN) resin, or any combination thereof. However, materials constituting the plurality of lenses 190 are not limited to the above examples.

Referring to FIG. 2, at least a portion of the first portion P1 of the reflective structure 150 may overlap at least portions of the plurality of lenses 190 in the vertical direction (Z direction). The back surface 150B of the first portion P1 of the reflective structure 150 may contact at least the portions of the plurality of lenses 190. According to an embodiment, at least the portions of the plurality of lenses 190 overlapping the first portion P1 in the vertical direction (Z direction) may be portions of edge regions of the plurality of lenses 190. According to an embodiment, a width 150W of the first portion P1 of the reflective structure 150 may be greater than a distance 190D between lenses 190 adjacent to each other. The width 150W of the first portion P1 of the reflective structure 150 may be 1 μm or greater.

A light source according to an embodiment may effectively prevent light leakage or crosstalk between pixels PX adjacent to each other based on a configuration in which the reflective structure 150 has a height to contact the plurality of lenses 190.

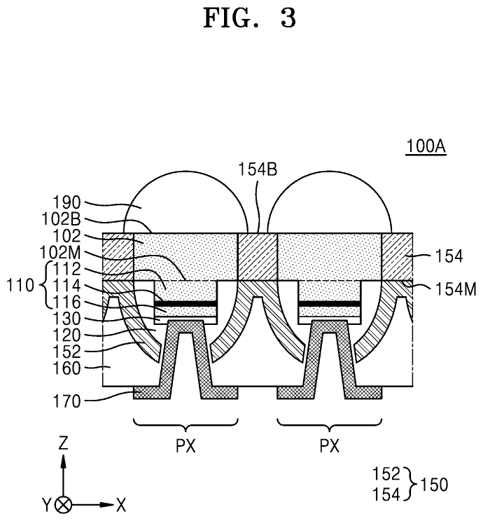

Referring to FIG. 3, the light source 100A may have a configuration that is substantially the same or similar to that of the light source 100 described above with reference to FIG. 2, and a difference is mainly described herein. The reflective structure 150 of the light source 100A according to an embodiment may include a capping layer 152 and a first metal layer 154. The capping layer 152 may surround sidewalls of the semiconductor light-emitting structure 110. The capping layer 152 may be spaced from the semiconductor light-emitting structure 110 in the horizontal direction with the insulation spacer 120 therebetween. The insulation layer 160 may cover the capping layer 152.

According to an embodiment, the first metal layer 154 may be disposed on the capping layer 152. The first metal layer 154 may be surrounded by the first conductive type base semiconductor layer 102. In other words, the first metal layer 154 may be arranged to penetrate through at least a portion of the first conductive type base semiconductor layer 102. The first metal layer 154 may contact at least portions of the plurality of lenses 190.

A back surface 154B of the first metal layer 154 may be coplanar with the back surface 102B of the first conductive type base semiconductor layer 102. A main surface 154M of the first metal layer 154 may contact the capping layer 152. A thickness of the first metal layer 154 may be substantially identical to a thickness of the first conductive type base semiconductor layer 102. The first metal layer 154 may be spaced apart from the light-emitting structure 110 in the horizontal direction (a direction on the X-Y plane) and the vertical direction (Z direction).

The capping layer 152 and the first metal layer 154 may each include, for example but not limited to, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), titanium (Ti), titanium nitride (TiN), tantalum (Ta), tantalum nitride (TaN), tungsten (W), or any combination thereof. According to an embodiment, the first metal layer 154 may be formed through a plating process.

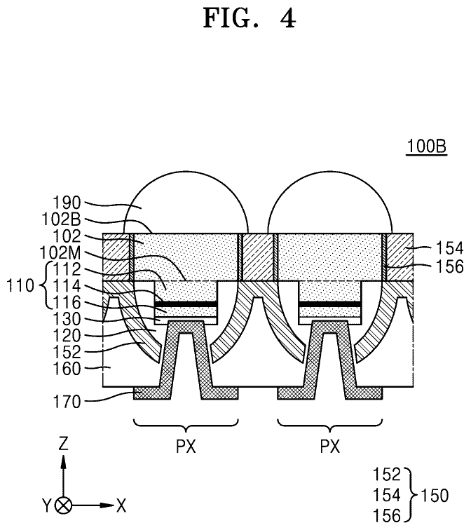

Referring to FIG. 4, the light source 100B may have a configuration that is substantially the same or similar to that of the light source 100A described above with reference to FIG. 3 and a difference is mainly described herein. The reflective structure 150 of the light source 100B according to an embodiment may include the capping layer 152, the first metal layer 154, and a second metal layer 156.

According to an embodiment, the second metal layer 156 may be disposed on sidewalls of the first metal layer 154. The second metal layer 156 may be provided between the first metal layer 154 and the first conductive type base semiconductor layer 102. The second metal layer 156 may penetrate through the first conductive type base semiconductor layer 102 in the vertical direction (Z direction). A thickness of the second metal layer 156 may be identical to the thickness of the first conductive type base semiconductor layer 102.

The second metal layer 156 may overlap the capping layer 152 in the vertical direction. According to an embodiment, the second metal layer 156 may contact the capping layer 152 and/or some of the plurality of lenses 190. The second metal layer 156 may include, for example but not limited to, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), titanium (Ti), titanium nitride (TiN), tantalum (Ta), tantalum nitride (TaN), tungsten (W), or any combination thereof. According to an embodiment, the second metal layer 156 may be deposited on the capping layer 152 and then filled by plating to form the first metal layer 154.

Referring to FIGS. 3 and 4, the light sources 100A and 100B according to various embodiments may prevent light leakage between the pixels PX adjacent to each other and improve current spreading by arranging the first metal layer 154 and/or the second metal layer 156 on the capping layer 152.

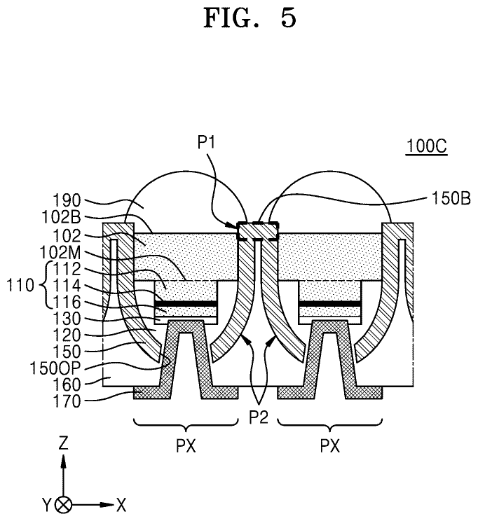

Referring to FIG. 5, the light source 100C may have a configuration that is substantially the same or similar to that of the light source 100 described above with reference to FIG. 2 and a difference is mainly described herein.

At least a portion of side surfaces of the reflective structure 150 included in the light source 100C according to an embodiment may be exposed without being covered by the first conductive type base semiconductor layer 102. At least the portion of side surfaces of the reflective structure 150 exposed by the first conductive type base semiconductor layer 102 may contact at least some of the plurality of lenses 190. In a process of forming the light source 100C, the reflective structure 150 may function as an etching stop film, and thus, as shown in FIG. 5, a vertical level of the back surface 150B of the first portion P1 of the reflective structure 150 may be higher than a vertical level of the back surface 102B of the first conductive type base semiconductor layer 102. According to an embodiment, the plurality of lenses 109 may be coated on the back surface 102B of the first conductive type base semiconductor layer 102 to cover at least a portion of the back surface 150B of the first portion P1 of the reflective structure 150.

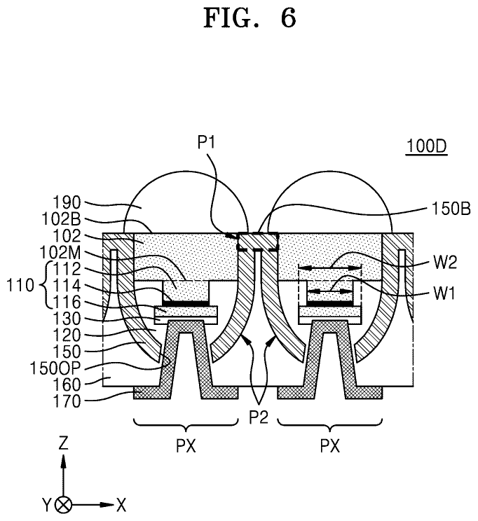

Referring to FIG. 6, the light source 100D may have a configuration that is substantially the same or similar to that of the light source 100 described above with reference to FIG. 2 and a difference is mainly described herein. The semiconductor light-emitting structure 110 included in the light source 100D according to various embodiments may include the first conductive type semiconductor layer 112, the active layer 114, and the second conductive type semiconductor layer 116 sequentially stacked in the vertical direction (Z direction) with respect to the main surface 102M of the first conductive type base semiconductor layer 102. According to an embodiment, the first conductive type semiconductor layer 112 may include a nitride semiconductor layer doped with an n-type dopant, and the second conductive type semiconductor layer 116 may include a nitride semiconductor layer doped with a p-type dopant.

According to an embodiment, a width W1 of the first conductive type semiconductor layer 112 may be less than a width W2 of the second conductive type semiconductor layer 116. A width of the active layer 114 may be less than the width W2 of the second conductive type semiconductor layer 116. A width of the transparent electrode layer 130 may be greater than the width W1 of the first conductive type semiconductor layer 112.

FIG. 7A is a schematic perspective view for illustrating the light source 100 as shown in FIG. 2. FIG. 7B is a schematic plan view of a semiconductor light-emitting structure 110 shown in FIG. 7A.

Referring to FIGS. 7A and 7B, from the planar perspective (X-Y plane), the first conductive type semiconductor layer 112, the active layer 114, and the second conductive type semiconductor layer 116 included in the semiconductor light-emitting structure 110 and the transparent electrode layer 130 may each have a rectangular planar shape. A width of the semiconductor light-emitting structure 110 in the horizontal direction (e.g., X direction or Y direction) parallel to the main surface 102M (refer to FIG. 2) of the first conductive type base semiconductor layer 102 may be about 100 μm or less, about 50 μm or less, about 20 μm or less, about 10 μm or less, about 6 μm or less, about 5 μm or less, about 4 μm or less, or about 2 μm or less, but is not limited thereto. In the horizontal direction (e.g., X direction or Y direction) parallel to the main surface 102M of the first conductive type base semiconductor layer 102, the transparent electrode layer 130 may have a width that is identical or similar to the width of the semiconductor light-emitting structure 110.

FIGS. 8A and 8B are diagrams for describing a light source 200 according to other embodiments. FIG. 8A is a schematic perspective view for describing example shapes of a semiconductor light-emitting structure 110A and the transparent electrode layer 130 included in the light source 200, and FIG. 8B is a schematic plan view for describing a planar shape of the semiconductor light-emitting structure 110A. In FIGS. 8A and 8B, the same reference numerals as those in FIG. 2 denote the same members, and detailed descriptions thereof will be omitted below.

Referring to FIGS. 8A and 8B, the light source 200 may have substantially the same or similar configuration as that of the light source 100 described with reference to FIG. 2. However, the light source 200 may include the semiconductor light-emitting structure 110A instead of the semiconductor light-emitting structure 110. The semiconductor light-emitting structure 110A may include a first conductive type semiconductor layer 112A, an active layer 114A, and a second conductive type semiconductor layer 116A.

The first conductive type semiconductor layer 112A, the active layer 114A, and the second conductive type semiconductor layer 116A may have substantially the same or similar configurations as those described with respect to the first conductive type semiconductor layer 112, the active layer 114, and the second conductive type semiconductor layer 116 with reference to FIG. 2. However, from the planar perspective (X-Y plane), the first conductive type semiconductor layer 112A, the active layer 114A, and the second conductive type semiconductor layer 116A included in the semiconductor light-emitting structure 110A may each have a circular planar shape.

The local recess 130R may be formed in a surface of the transparent electrode layer 130 opposite to a surface of the transparent electrode layer 130 in contact with the semiconductor light-emitting structure 110A. A portion of the reflective electrode layer 170 illustrated in FIG. 2 may be accommodated in the local recess 130R of the transparent electrode layer 130.

FIGS. 8C and 8D are plan views for describing light sources 200A and 200B according to other embodiments. FIG. 8C is a schematic plan view for describing an example planar shape of a semiconductor light-emitting structure 110B included in the light source 200A, and FIG. 8D is a schematic plan view for describing an example planar shape of a semiconductor light-emitting structure 110C included in the light source 200B.

Referring to FIG. 8C, the light source 200A may have substantially the same or similar configuration as that of the light source 100 described with reference to FIG. 2. However, the light source 200A may include the semiconductor light-emitting structure 110B. The semiconductor light-emitting structure 110B may have substantially the same or similar configuration as the semiconductor light-emitting structure 110 described above with reference to FIG. 2. However, from the planar perspective (X-Y plane), the semiconductor light-emitting structure 110B may have a planar shape of a rectangle with rounded corners.

Referring to FIG. 8D, the light source 200B may have substantially the same or similar configuration as that of the light source 100 described with reference to FIG. 2. However, the light source 200B may include the semiconductor light-emitting structure 110C. The semiconductor light-emitting structure 110C may have substantially the same or similar configuration as the semiconductor light-emitting structure 110 described above with reference to FIG. 2. However, from the planar perspective (X-Y plane), the semiconductor light-emitting structure 110B may have a planar shape of a hexagon.

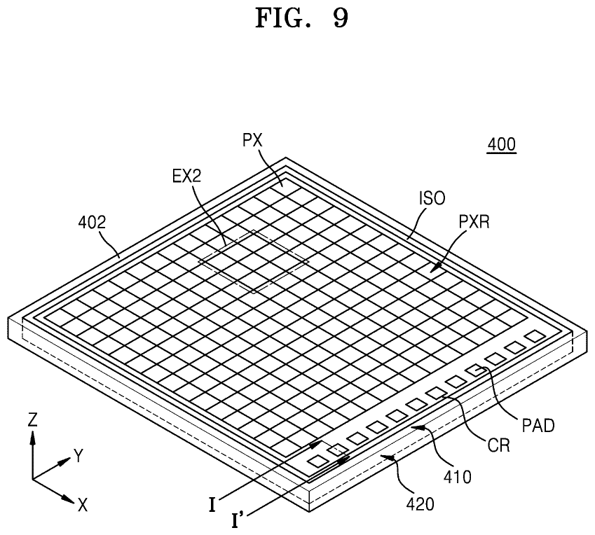

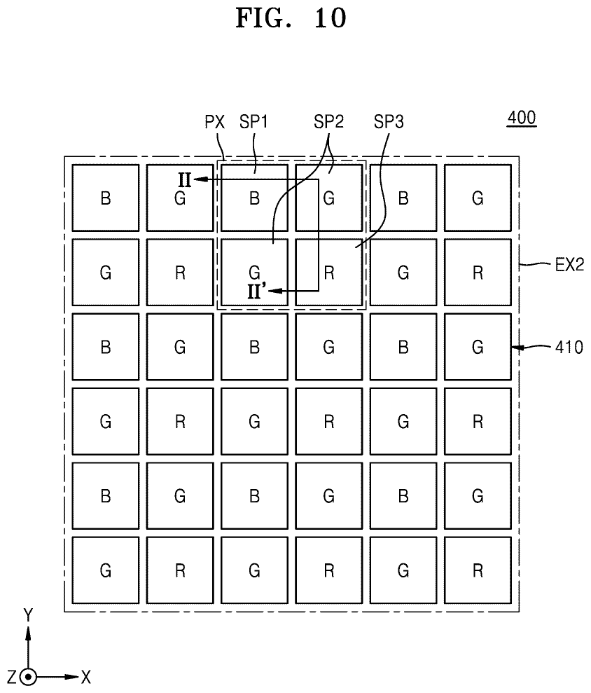

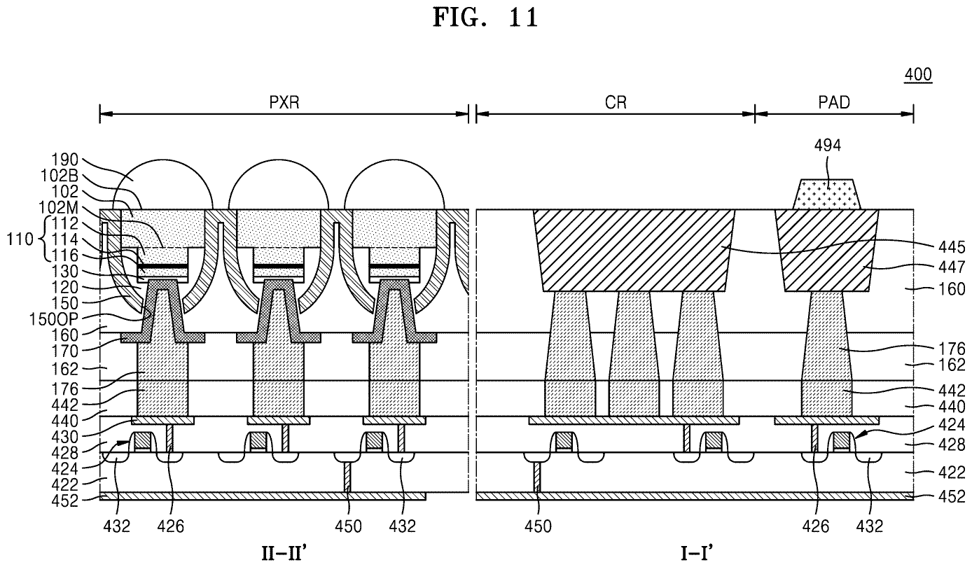

FIGS. 9 to 11 are diagrams for describing a display apparatus 400 according to embodiments. FIG. 9 is a schematic perspective view of the display apparatus 400 according to embodiments, FIG. 10 is an enlarged plan view of a portion EX2 in FIG. 9, and FIG. 11 is a schematic cross-sectional view of components of a portion taken along a line I-I′ of FIG. 9 and a portion taken along a line II-II′ of FIG. 10.

Referring to FIGS. 9 to 11, the display apparatus 400 may include a pixel array 410 and a circuit board 420 arranged to overlap each other in the vertical direction (Z direction in FIG. 9). The circuit board 420 may include driving circuits. The pixel array 410 may include the plurality of pixels PX arranged in the pixel region PXR on the circuit board 420. The display apparatus 400 may further include a frame 402 surrounding the pixel array 410 and the circuit board 420.

The circuit board 420 may be a driving circuit board including a plurality of transistors. According to embodiments, the circuit board 420 may include an application-specific integrated circuit (ASIC) having a plurality of driver circuits. According to embodiments, the circuit board 420 may include a flexible substrate. In this case, the display apparatus 400 may be implemented as a variable or curved display apparatus.

The pixel array 410 may include the pixel region PXR in which the plurality of pixels PX are arranged, a plurality of connection pad regions PAD in which connection pad electrodes 494 are arranged, a connection region CR for interconnecting the pixels PX and the connection pad electrodes 494, and an edge region ISO.

The plurality of pixels PX may include a plurality of first sub-pixels SP1, a plurality of second sub-pixels SP2, and a plurality of third sub-pixels SP3 configured to emit light of particular wavelengths, e.g., light of particular colors. According to embodiments, first to third sub-pixels SP1, SP2, and SP3 may be configured to emit blue (B) light, green (G) light, and red (R) light, respectively. According to embodiments, the plurality of pixels PX may each include first to third sub-pixels SP1, SP2, and SP3 arranged in a Bayer pattern. In other words, the plurality of pixels PX may each include a first sub-pixel SP1 and a third sub-pixel SP3 arranged in a first diagonal direction and two second sub-pixels SP2 arranged in a second diagonal direction intersecting the first diagonal direction. Although FIG. 10 illustrates an example in which the first to third sub-pixels SP1, SP2, and SP3 in each of the plurality of pixels PX are arranged in a 2×2 Bayer pattern, the disclosure is not limited thereto. For example, the plurality of pixels PX may each be configured in a different arrangement, such as 3×3 or 4×4. According to still other embodiments, some other pixels PX may be configured to emit light of a color other than R, G, and B, e.g., yellow light. In the pixel array 410 of FIG. 9, the plurality of pixels PX are illustrated in a form of a 15×15 arrangement in the first horizontal direction (X direction) and the second horizontal direction (Y direction), but the disclosure is not limited thereto. The pixel array 410 may include any suitable number of pixels PX in a row-wise direction and a column-wise direction, e.g., the plurality of pixels PX having an array of 1,024×768.

The plurality of connection pad regions PAD may be arranged along an edge of the display apparatus 400 on at least one side of the pixel region PXR. The plurality of connection pad regions PAD may be electrically connected to the plurality of pixels PX and driving circuits of the circuit board 420. An external device and the display apparatus 400 may be electrically connected through the plurality of connection pad regions PAD. The number of connection pad regions PAD included in the display apparatus 400 may vary. According to embodiments, the number of connection pad regions PAD included in the display apparatus 400 may be determined depending on the number of pixels PX included in the pixel array 410, a driving method of the driving circuit included in the circuit board 420, etc.

The connection region CR may be a region between the pixel region PXR and the plurality of connection pad regions PAD. In the connection region CR, wiring structures electrically connected to the plurality of pixels PX and a common electrode 445 may be arranged.

The edge region ISO of the display apparatus 400 may be a region along edges of the pixel array 410. The semiconductor light-emitting structure 110 may not be disposed in the edge region ISO.

The frame 402 of the display apparatus 400 may be disposed around the pixel array 410 and serve as a guide to define an arrangement space of the pixel array 410. The frame 402 may include, for example but not limited to, a polymer, a ceramic, a semiconductor, a metal, or any combination thereof.

As shown in FIG. 11, the circuit board 420 may include a semiconductor substrate 422, a driving circuit including a plurality of driving elements 424 on the semiconductor substrate 422 and including transistors, a plurality of interconnections 426 electrically connected to the plurality of driving elements 424, and a plurality of wiring lines 430 connected to the plurality of interconnections 426. The plurality of driving elements 424 constituting the driving circuit, the plurality of interconnections 426, and the plurality of wiring lines 430 may be covered by an insulation layer 428. The circuit board 420 may further include a first bonding insulation layer 440 on the insulation layer 428 and a plurality of first bonding electrodes 442 penetrating through the first bonding insulation layer 440 and connected to the plurality of wiring lines 430.

The semiconductor substrate 422 may include a plurality of impurity regions 432 that constitute source/drain regions of a plurality of transistors constituting the plurality of driving elements 424. The semiconductor substrate 422 may include a semiconductor such as silicon (Si) or germanium (Ge), or may include a compound semiconductor such as SiGe, SiC, GaAs, InAs, or InP. The semiconductor substrate 422 may further include a plurality of via electrodes 450, such as through silicon vias (TSVs), connected to the driving circuit, and a plurality of substrate wiring lines 452 connected to the plurality of via electrodes 450.

The driving circuit may be a circuit for controlling driving of the pixel PX or the first to third sub-pixels SP1, SP2, and SP3. Some of the plurality of impurity regions 432 may be electrically connected to at least one selected from among the plurality of first to third sub-pixels SP1, SP2, and SP3 via an interconnection 426, a wiring line 430, and a first bonding electrode 442. According to embodiments, some of the plurality of impurity regions 432 may be connected to one of the plurality of substrate wiring lines 452 through a via electrode 450.

Top surfaces of the plurality of first bonding electrodes 442 and a top surface of the first bonding insulation layer 440 may provide a top surface of the circuit board 420. The plurality of first bonding electrodes 442 included in the circuit board 420 may be bonded to a plurality of second bonding electrodes 176 included in the pixel array 410 to provide an electrical connection path. According to embodiments, the plurality of first bonding electrodes 442 and the plurality of second bonding electrodes 176 may each include, for example but not limited to, a copper (Cu) film. The plurality of first bonding electrodes 442 and the plurality of second bonding electrodes 176 may each further include, for example but not limited to, a barrier metal layer surrounding the Cu film. The barrier metal layer may include Ta, TaN, or any combination thereof.

The first bonding insulation layer 440 included in the circuit board 420 may be bonded to a second bonding insulation layer 162 included in the pixel array 410. The first bonding insulation layer 440 and the second bonding insulation layer 162 may each include, for example but not limited to, SiO, SiN, SiCN, SiOC, SiON, SiOCN, or any combination thereof.

In the pixel array 410, the first to third sub-pixels SP1, SP2, and SP3 may each include the semiconductor light-emitting structure 110 as described with reference to FIG. 2. In the pixel array 410, the plurality of semiconductor light-emitting structures 110 may be spaced apart from one another in a horizontal direction parallel to a main surface 110M of the first conductive type base semiconductor layer 102. The plurality of semiconductor light-emitting structures 110 may each include the first conductive type semiconductor layer 112, the active layer 114, and the second conductive type semiconductor layer 116 sequentially stacked in a vertical direction (Z direction) perpendicular to the main surface 110M of the first conductive type base semiconductor layer 102. Detailed configurations of the first conductive type semiconductor layer 112, the active layer 114, and the second conductive type semiconductor layer 116 may be as described above with reference to FIG. 2.

The pixel array 410 of the display apparatus 400 may further include a plurality of transparent electrode layers 130, the reflective structure 150, and the reflective electrode layer 170 penetrating through the reflective structure 150 and contacting the transparent electrode layer 130. Detailed configurations of the transparent electrode layer 130, the reflective structure 150, and the reflective electrode layer 170 may be as described above with reference to FIG. 2.

The plurality of semiconductor light-emitting structures 110 included in the pixel array 410 of the display apparatus 400 may be configured to emit light having a wavelength λ selected within a range from about 400 nm to about 700 nm, e.g., a wavelength λ selected within a range from about 490 nm to 700 nm.

In the pixel array 410 of the display apparatus 400, the plurality of second bonding electrodes 176 may be connected to a plurality of reflective electrode layers 170, and the second bonding insulation layer 162 surrounding the plurality of second bonding electrodes 176 may contact a portion of the reflective electrode layer 170 and may contact the insulation layer 160 covering the reflective structure 150.

The display apparatus 400 may further include the common electrode 445 and an inner pad electrode 447. The insulation layer 160 covering the reflective electrode layer 170 in the pixel array 410 may extend to the connection region CR and a connection pad region PAD to cover the common electrode 445 and the inner pad electrode 447. A connection pad electrode 494 may be disposed on the inner pad electrode 447 in the connection pad region PAD.

The plurality of second bonding electrodes 176 may be connected to the common electrode 445. The common electrode 445 may have a ring-like shape or a rectangular ring-like ring shape surrounding the pixel region PXR parallel to the main surface 102M of the first conductive type base semiconductor layer 102 in a plan view. However, the arrangement of the common electrode 445 may be changed in various ways as needed.

The connection pad electrode 494 may be disposed on the inner pad electrode 447 in the connection pad region PAD. The inner pad electrode 447 may contact the connection pad electrode 494. The inner pad electrode 447 may be provided between the connection pad electrode 494 and the second bonding electrode 176 to interconnect the connection pad electrode 494 and the second bonding electrode 176. The common electrode 445 and the inner pad electrode 447 may include, for example but not limited to, a conductive material, e.g., silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), or any combination thereof.

The connection pad electrode 494 may be connected to an external device or an external IC capable of applying an electrical signal to the circuit board 420 through wire bonding or anisotropic conductive film (AFC) bonding. The connection pad electrode 494 may electrically interconnect the driving circuits of the circuit board 420 and the external device. The connection pad electrode 494 may include, for example but not limited to, a metal, such as gold (Au), silver (Ag), nickel (Ni), etc.

From among the plurality of second bonding electrodes 176, a second bonding electrode 176 disposed in the pixel region PXR may be connected to the reflective electrode layer 170, a second bonding electrode 176 disposed in the connection region CR may be connected to the common electrode 445, and a second bonding electrode 176 disposed in the connection pad region PAD may be connected to the inner pad electrode 447.

A surface of the second bonding insulation layer 162 facing the circuit board 420 and surfaces of the plurality of second bonding electrodes 176 facing the circuit board 420 may extend in one plane. The second bonding insulation layer 162 may form a dielectric-dielectric bond with the first bonding insulation layer 440. The circuit board 420 and the pixel array 410 may be bonded by bonding the plurality of first bonding electrodes 442 and the plurality of second bonding electrodes 176 and bonding the first bonding insulation layer 440 and the second bonding insulation layer 162.

According to embodiments, the bonding of the plurality of first bonding electrodes 442 and the plurality of second bonding electrodes 176 may be, for example, copper (Cu)-copper (Cu) bonding, and the bonding of the first bonding insulation layer 440 and the second bonding insulation layer 162 may be, for example, dielectric-dielectric bonding, such as SiCN-SiCN bonding. The circuit board 420 and the pixel array 410 may be bonded through hybrid bonding including copper (Cu)-copper (Cu) bonding and dielectric-dielectric bonding, and may be bonded without a separate adhesive layer.

In the display apparatus 400, the reflective structure 150 may be arranged to surround sidewalls of the semiconductor light-emitting structure 110. The reflective structure 150 may include a first portion P1 parallel to the horizontal direction (a direction on the X-Y plane) and the second portion P2 extending in the vertical direction at an angle from an end portion of the first portion P1, as described above with reference to FIG. 2. The first portion P1 of the reflective structure 150 may contact at least a portion of the plurality of lenses 190. The reflective structure 150 may penetrate through at least a portion of the first conductive type base semiconductor layer 102. Therefore, the display apparatus 400 may prevent light leakage between adjacent pixels, e.g., between the first to third sub-pixels SP1, SP2, and SP3, and improve light extraction efficiency.

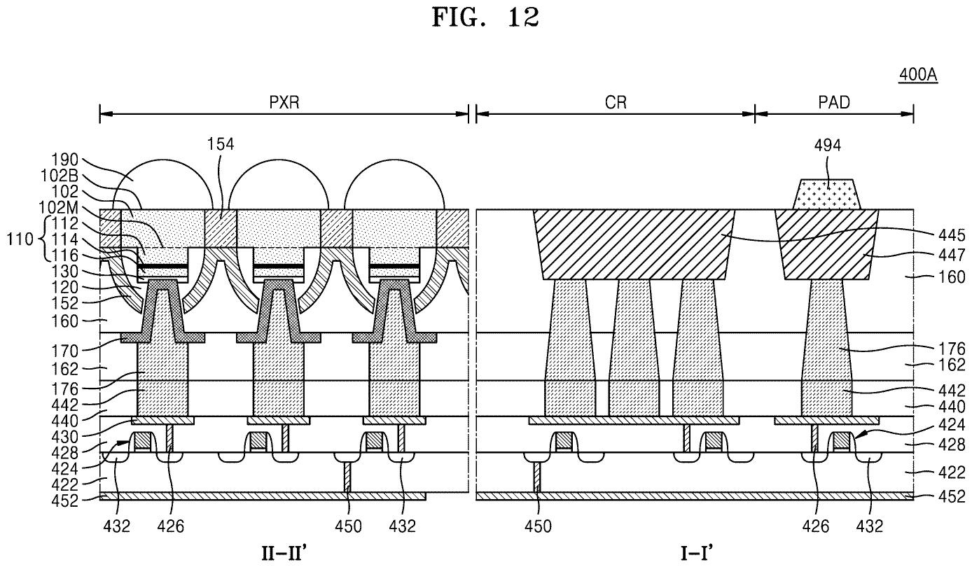

FIGS. 12 to 14 are diagrams for describing display apparatuses 400A, 400B, and 400C according to embodiments. In FIGS. 12 to 14, reference numerals identical to those of FIGS. 1 to 11 denote the same elements, and redundant descriptions thereof are omitted.

Referring to FIG. 12, the display apparatus 400A may have substantially the same or similar configuration as the display apparatus 400 described above with reference to FIGS. 9 to 11. However, the reflective structure 150 of the display apparatus 400A may include the capping layer 152 and the first metal layer 154. The descriptions of the capping layer 152 and the first metal layer 154 may be identical to those given above with reference to FIG. 3.

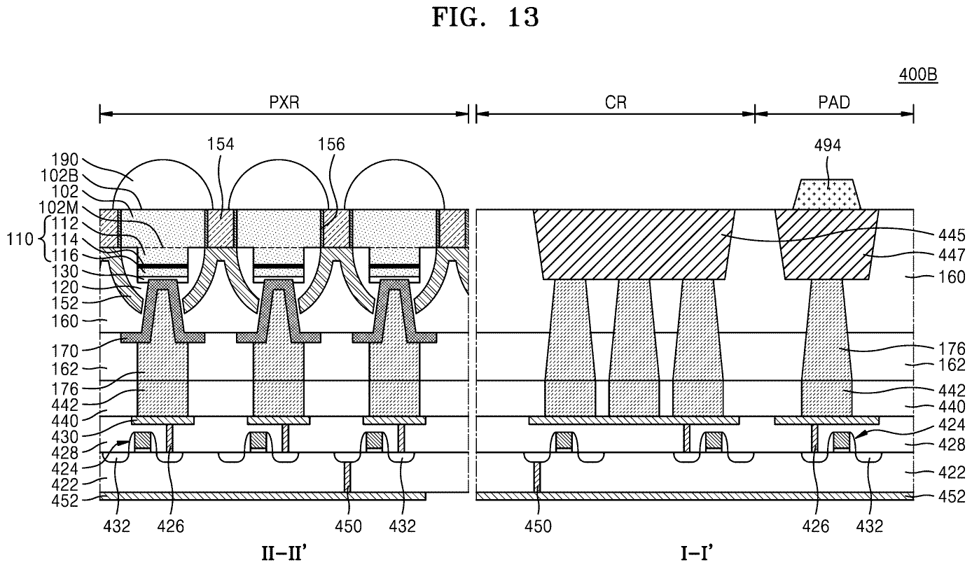

Referring to FIG. 13, the display apparatus 400B may have substantially the same or similar configuration as the display apparatus 400 described above with reference to FIGS. 9 to 11. However, the reflective structure 150 of the display apparatus 400B may include the capping layer 152, the first metal layer 154, and the second metal layer 156. The descriptions of the capping layer 152, the first metal layer 154, and the second metal layer 156 may be identical to those given above with reference to FIG. 4.

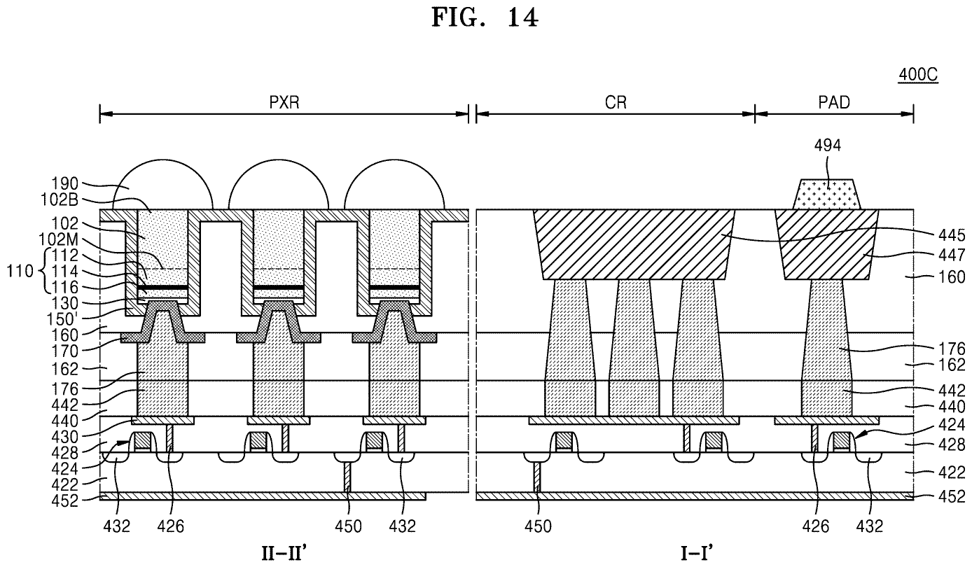

Referring to FIG. 14, the display apparatus 400C may have substantially the same or similar configuration as the display apparatus 400 described above with reference to FIGS. 9 to 11. However, the insulation spacer 120 (refer to FIG. 11) surrounding the semiconductor light-emitting structure 110 may be omitted in the display apparatus 400C. Therefore, a reflective structure 150′ may contact a side surface of the semiconductor light-emitting structure 110, a side surface of the transparent electrode layer 130, and a portion of the reflective electrode layer 170.

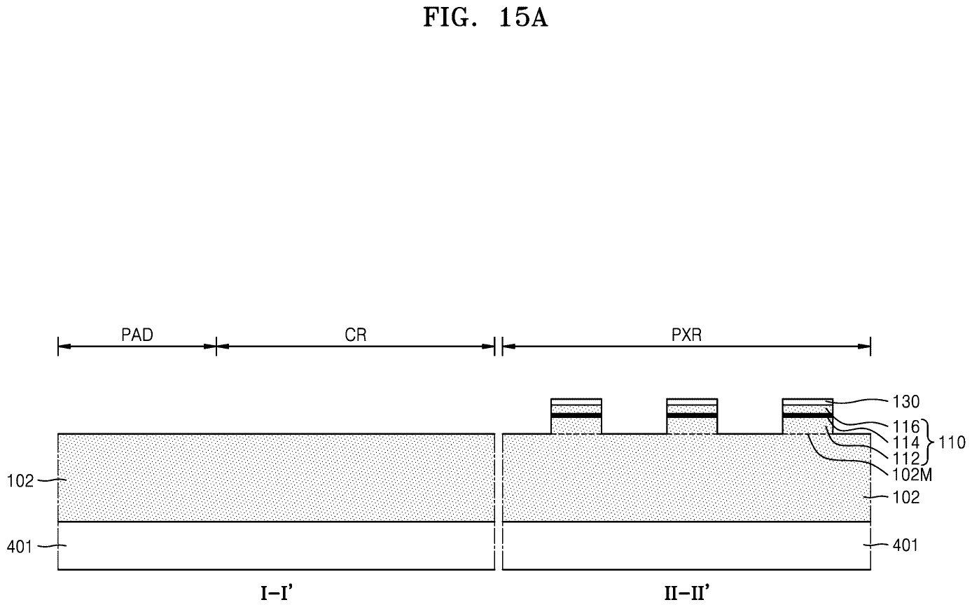

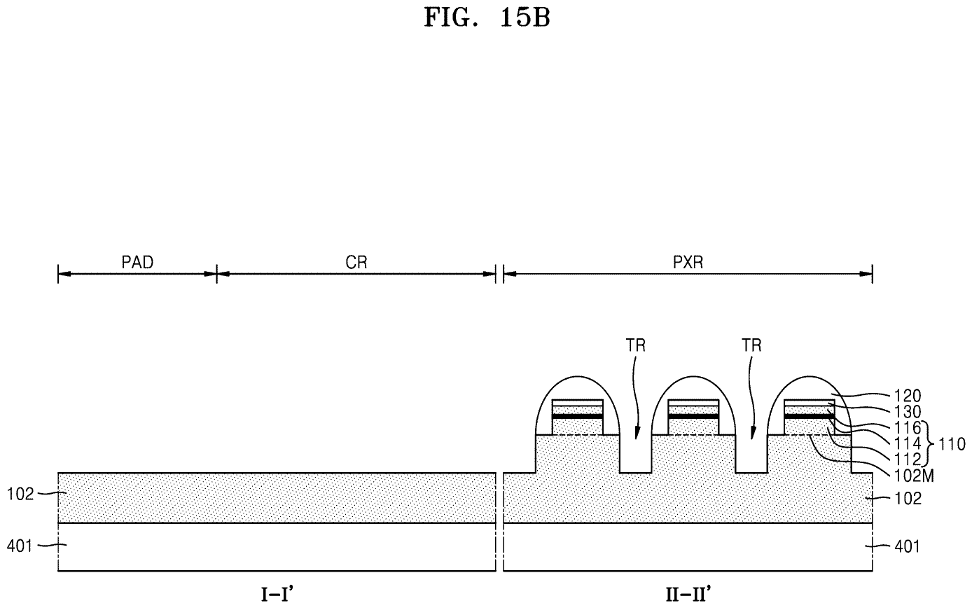

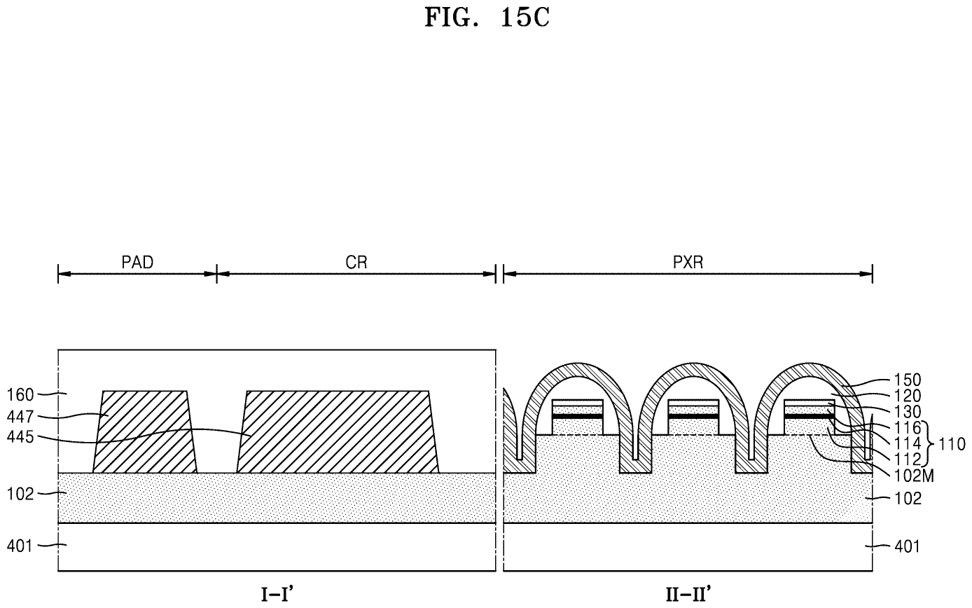

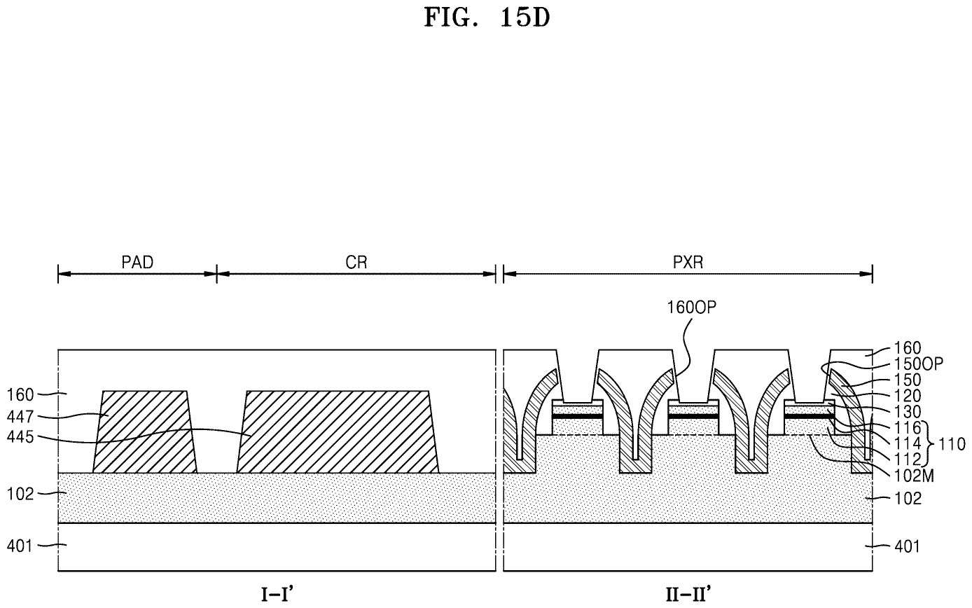

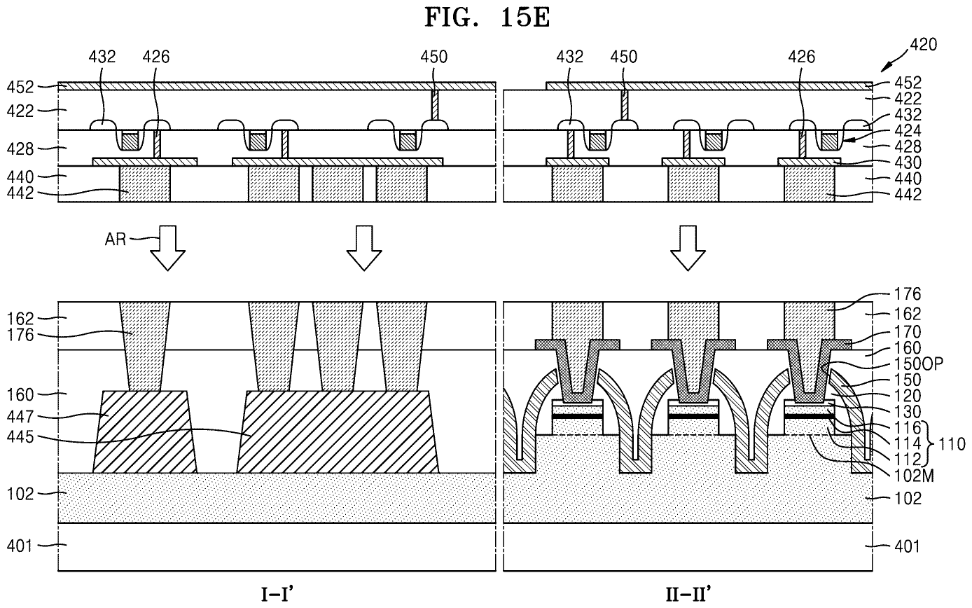

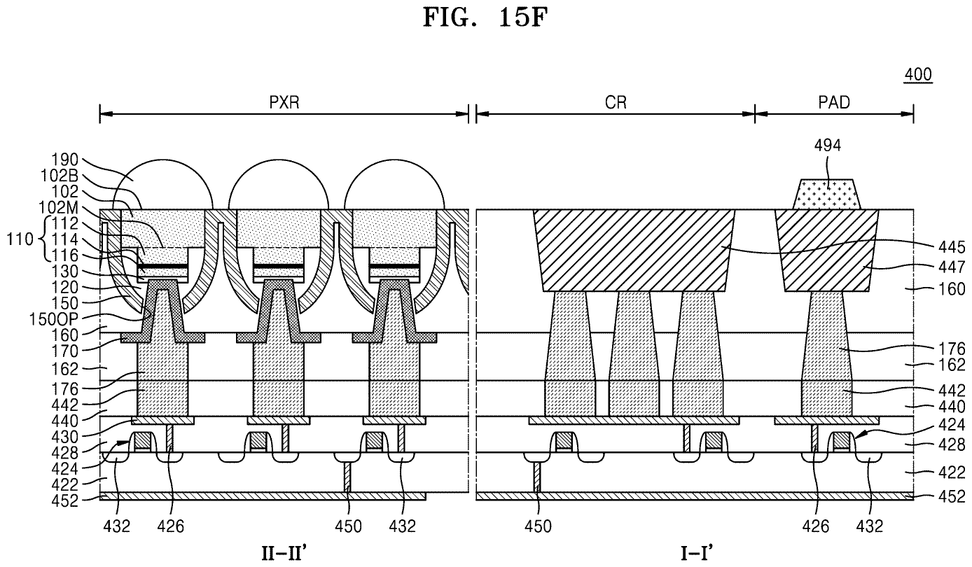

FIGS. 15A to 15F are cross-sectional views of a method of manufacturing a display apparatus including a light source according to a process sequence, according to embodiments. Referring to FIGS. 15A to 15F, a method of manufacturing the display apparatus 400 shown in FIG. 11 will be described as an example. In FIGS. 15A to 15F, reference numerals identical to those of FIG. 11 denote the same elements, and redundant descriptions thereof are omitted.

Referring to FIG. 15A, a semiconductor single crystal growing process, a deposition process, an etching process, etc. using a growth substrate 401 may be used to form a structure including the first conductive type base semiconductor layer 102 on the growth substrate 401, the plurality of semiconductor light-emitting structures 110 arranged in the pixel region PXR and each including the first conductive type semiconductor layer 112, the active layer 114, and the second conductive type semiconductor layer 116, and the plurality of transparent electrode layers 130 covering the plurality of semiconductor light-emitting structures 110.

The growth substrate 401 may be a substrate for growing a semiconductor single crystal and may include, for example but not limited to, AlN, AlGaN, ZnO, GaAs, MgAl₂O₄, MgO, LiAlO₂, LiGaO₂, GaN, or any combination thereof. According to embodiments, to improve crystallinity and light extraction efficiency of semiconductor layers, at least a portion of the top surface of the growth substrate 401 may have a concavo-convex structure. In this case, concavo-convex portions may be formed on layers being grown on top.

According to embodiments, to form the structure shown in FIG. 15A, the first conductive type base semiconductor layer 102, the first conductive type semiconductor layer 112, the active layer 114, and the second conductive type semiconductor layer 116 may be sequentially formed on the growth substrate 401, the transparent electrode layer 130 may be formed on the second conductive type semiconductor layer 116, and then the transparent electrode layer 130, the second conductive type semiconductor layer 116, the active layer 114, and the first conductive type semiconductor layer 112 may be partially etched through an etching process using a hard mask pattern as an etching mask such that the plurality of semiconductor light-emitting structures 110 spaced apart from each other on the first conductive type base semiconductor layer 102 and the plurality of transparent electrode layers 130 covering the plurality of semiconductor light-emitting structures 110 remain. The plurality of semiconductor light-emitting structures 110 may form a plurality of pillar-like structures having a circular, an elliptical, or a polygonal planar shape together with the plurality of transparent electrode layers 130.

The first conductive type base semiconductor layer 102, the first conductive type semiconductor layer 112, the active layer 114, and the second conductive type semiconductor layer 116 may be formed through a metal organic chemical vapor deposition (MOCVD), a hydride vapor phase epitaxy (HVPE), or a molecular beam epitaxy (MBE) process. Detailed configurations of the first conductive type base semiconductor layer 102, the first conductive type semiconductor layer 112, the active layer 114, and the second conductive type semiconductor layer 116 may be as described above with reference to FIG. 2.

According to embodiments, a wet etching process may be further performed to remove damaged regions due to etching in each of the plurality of semiconductor light-emitting structures 110. In the wet etching process, by controlling process conditions such that crystal planes are etched with a different selectivity, only damaged regions in each of the plurality of semiconductor light-emitting structures 110 may be selectively removed, and sidewalls of each of the plurality of semiconductor light-emitting structures 110 may have a profile that extends in a vertical direction with respect to the main surface 102M of the first conductive type base semiconductor layer 102. Also, non-radiative recombination due to damaged regions in the sidewalls of each of the plurality of semiconductor light-emitting structures 110 is reduced, and thus brightness of a light source to be formed may be improved.

Referring to FIG. 15B, the plurality of insulation spacers 120 covering the plurality of semiconductor light-emitting structures 110 may be formed on the first conductive type base semiconductor layer 102. The plurality of insulation spacers 120 may be formed to cover the sidewalls of each of the plurality of semiconductor light-emitting structures 110 and the sidewalls and the top surface of the transparent electrode layer 130. Thereafter, a trench TR may be formed between plurality of semiconductor light-emitting structures 110. According to an embodiment, a depth of the trench TR may be 300 nm or greater. According to an embodiment, the thickness of the first conductive type base semiconductor layer 102 may be reduced in the connection region CR and the connection pad region PAD by removing a portion of the first conductive type base semiconductor layer 102.

Referring to FIG. 15C, the reflective structure 150 may be formed to cover the insulation spacer 120 and the trench TR. The common electrode 445 disposed on the first conductive type base semiconductor layer 102 in the connection region CR and the inner pad electrode 447 disposed on the first conductive type base semiconductor layer 102 in the connection pad region PAD may be formed.

Referring to FIG. 15D, the opening 150OP of the reflective structure 150 that opens a region overlapping the semiconductor light-emitting structure 110 may be formed, the insulation layer 160 covering the reflective structure 150, the common electrode 445 in the connection region CR, and the inner pad electrode 447 in the connection pad region PAD may be formed, and then a plurality of contact holes overlapping the opening 150OP of the reflective structure 150 may be formed. At this time, a portion of each of the plurality of transparent electrode layers 130 exposed through the plurality of contact holes may be etched by over-etching, and thus the local recess 130R (refer to FIG. 7A) may be formed on an exposed surface of each of the plurality of transparent electrode layers 130.

Referring to FIG. 15E, the plurality of reflective electrode layers 170 may be formed on the plurality of transparent electrode layers 130. After forming the second bonding insulation layer 162 covering the plurality of reflective electrode layers 170 and the insulation layer 160 in the pixel region PXR and covering the insulation layer 160 in the connection region CR and the connection pad region PAD, some regions of the second bonding insulation layer 162 in the pixel region PXR, the connection region CR, and the connection pad region PAD may be etched to form a plurality of via holes exposing the plurality of reflective electrode layers 170, the common electrode 445, and the inner pad electrode 447, and then the plurality of second bonding electrodes 176 filling a plurality of exposed via holes may be formed.

Referring to FIG. 15E, after preparing the circuit board 420, the circuit board 420 may be positioned such that the second bonding insulation layer 162 and the plurality of second bonding electrodes 176 face the first bonding insulation layer 440 and the plurality of first bonding electrodes 442 included in the circuit board 420, respectively, and the circuit board 420 may be pressed in a direction indicated by an arrow AR on a surface on which the second bonding insulation layer 162 and the plurality of second bonding electrodes 176 are exposed, such that bonding of the plurality of first bonding electrodes 442 and the plurality of second bonding electrodes 176 and bonding of the first bonding insulation layer 440 and the second bonding insulation layer 162 are formed.

The bonding of the plurality of first bonding electrodes 442 and the plurality of second bonding electrodes 176 and the bonding of the first bonding insulation layer 440 and the second bonding insulation layer 162 may be accomplished through wafer bonding, for example, the hybrid bonding described above.

Referring to FIG. 15F, in a result structure in which the plurality of first bonding electrodes 442 and the plurality of second bonding electrodes 176 are bonded and the first bonding insulation layer 440 and the second bonding insulation layer 162 are bonded according to the process described above with reference to FIG. 15E, the growth substrate 401 covering the first conductive type base semiconductor layer 102 may be removed to expose the first conductive type base semiconductor layer 102. The growth substrate 401 may be removed through various processes such as laser lift-off, mechanical polishing or mechanical chemical polishing (chemical mechanical polishing (CMP)), and an etching process. After the growth substrate 401 is removed to expose the first conductive type base semiconductor layer 102, the thickness of the first conductive type base semiconductor layer 102 may be reduced through a polishing process such as the chemical mechanical polishing (CMP) process. Thereafter, the plurality of lenses 190 may be formed on the back surface 102B of the first conductive type base semiconductor layer 102 that overlaps the semiconductor light-emitting structure 110 in the vertical direction (Z direction).

Although a method of manufacturing the display apparatus 400 shown in FIG. 11 has been described with reference to FIGS. 15A to 15F as an example, one of ordinary skill in the art will readily appreciate that various modifications and changes may be made within the scope of the disclosure from the descriptions given above with reference to FIGS. 15A to 15F, thereby manufacturing display apparatuses having various structures that are variously changed within the scope of the disclosure from the display apparatus 400.

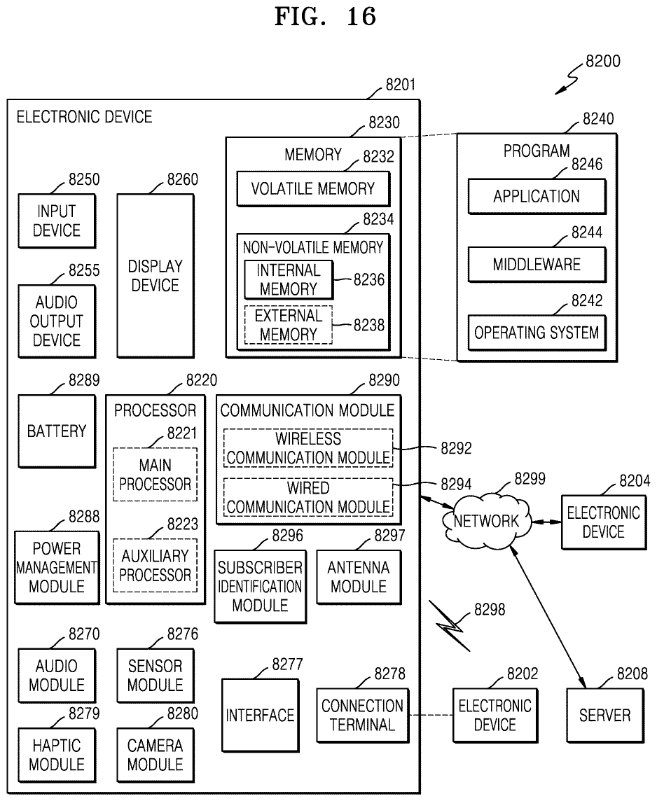

FIG. 16 is a block diagram an electronic device including a light source or a display apparatus, according to embodiments.

Referring to FIG. 16, an electronic device 8201 may be provided within a network environment 8200. In the network environment 8200, the electronic device 8201 may communicate with another electronic device 8202 via a first network 8298 (e.g., a short-range wireless communication network) or may communicate with another electronic device 8204 and/or a server 8208 via a second network 8299 (e.g., a long-range wireless communication network). The electronic device 8201 may communicate with the electronic device 8204 via the server 8208. The electronic device 8201 may include a processor 8220, a memory 8230, an input device 8250, an audio output device 8255, a display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic device 8201, some of these components may be omitted, or other components may be added. Some of the components may be implemented as a single integrated circuit. For example, the sensor module 8276 (e.g., a fingerprint sensor, an iris sensor, or an illuminance sensor) may be embedded in the display apparatus 8260 (e.g., a display).

The processor 8220 may execute software (e.g., a program 8240) to control one or more other components (e.g., hardware, software components, etc.) of the electronic device 8201 connected to the processor 8220 and perform various data processing or operations. As a part of data processing or calculation, the processor 8220 may load commands and/or data received from other components (e.g., the sensor module 8276, the communication module 8290, etc.) into a volatile memory 8232, process commands and/or data stored in the volatile memory 8232, and store result data in a non-volatile memory 8234. The processor 8220 may include a main processor 8221 (e.g., a central processing unit, an application processor, etc.) and an auxiliary processor 8223 (e.g., a graphics processing unit, an image signal processor, a sensor hub processor, a communication processor, etc.) that may operate independently or together with the main processor 8221. The auxiliary processor 8223 uses less power than the main processor 8221 and may perform specialized functions.

The auxiliary processor 8223 may control functions and/or states related to some of the components of the electronic device 8201 (e.g., the display apparatus 8260, the sensor module 8276, and the communication module 8290) on behalf of the main processor 8221 while the main processor 8221 is in an inactive state (sleep state) or together with the main processor 8221 while the main processor 8221 is in an active state (application execution state). The auxiliary processor 8223 (e.g., an image signal processor, a communication processor, etc.) may also be implemented as portion of other functionally related components (e.g., the camera module 8280, the communication module 8290, etc.).

The memory 8230 may store various data needed by components (e.g., the processor 8220, the sensor module 8276, etc.) of the electronic device 8201. The data may include, for example, input data and/or output data for software (such as the program 8240) and instructions associated therewith. The memory 8230 may include the volatile memory 8232 and/or the non-volatile memory 8234.

The program 8240 may be stored as software in the memory 8230 and may include an operating system 8242, middleware 8244, and/or an application 8246.

The input device 8250 may receive commands and/or data to be used in components (e.g., the processor 8220) of the electronic device 8201 from an external source (e.g., a user) of the electronic device 8201. The input device 8250 may include a remote controller, a microphone, a mouse, a keyboard, and/or a digital pen (e.g., a stylus pen).

The audio output device 8255 may output an audio signal to an outside of the electronic device 8201. The audio output device 8255 may include a speaker and/or a receiver. A speaker may be used for general purposes such as playback of multimedia or playback of recordings, and a receiver may be used to receive incoming calls. The receiver may be integrated as a portion of the speaker or implemented as a separate, independent device.

The display apparatus 8260 may visually provide information to the outside of the electronic device 8201. The display apparatus 8260 may include a display, a holographic device, or a projector and may include a control circuit for controlling a corresponding device. The display apparatus 8260 may include at least one of light sources having various structures as exemplified in FIGS. 1 to 6 and display apparatuses having various structures as exemplified in FIGS. 9 to 14. The display apparatus 8260 may include a touch circuitry configured to detect a touch, and/or a sensor circuitry (such as a pressure sensor) configured to measure the intensity of a force generated by a touch.

The audio module 8270 may convert sound into an electrical signal, or vice versa. The audio module 8270 may obtain sound through the input device 8250, or output sound through speakers and/or headphones of the audio output device 8255 and/or another electronic device (e.g., the electronic device 8202) directly or wirelessly connected to the electronic device 8201.

The sensor module 8276 may detect an operating status (e.g., power, temperature, etc.) of the electronic device 8201 or an external environmental status (e.g., user status, etc.) and generate an electrical signal and/or data value corresponding to a detected status. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an ambient light sensor.

The interface 8277 may support one or more designated protocols that may be used to allow the electronic device 8201 to connect directly or wirelessly with another electronic device (e.g., the electronic device 8202). The interface 8277 may include a high definition multimedia interface (HDMI), a universal serial bus (USB) interface, a secure digital (SD) card interface, and/or an audio interface.

A connection terminal 8278 may include a connector that allows the electronic device 8201 to be physically connected to another electronic device (e.g., the electronic device 8202). The connection terminal 8278 may include an HDMI connector, a USB connector, an SD card connector, and/or an audio connector (e.g., a headphone connector).

The haptic module 8279 may convert electrical signals into mechanical stimuli (e.g., vibration, movement, etc.) or electrical stimuli that a user may perceive through tactile or kinesthetic sensations. The haptic module 8279 may include a motor, a piezoelectric element, and/or an electrical stimulation device.

The camera module 8280 may capture still images and/or videos. The camera module 8280 may include a lens assembly including one or more lenses, image sensors, image signal processors, and/or flashes. A lens assembly included in the camera module 8280 may collect light emitted from a target object of image capture.

The power management module 8288 may manage power supplied to the electronic device 8201. The power management module 8388 may be implemented as portion of a power management integrated circuit (PMIC).

The battery 8289 may supply power to components of the electronic device 8201. The battery 8289 may include a non-rechargeable primary battery, a rechargeable secondary battery, and/or a fuel cell.

The communication module 8290 may support establishment of a direct (wired) communication channel and/or a wireless communication channel between the electronic device 8201 and another electronic device (e.g., the electronic device 8202, the electronic device 8204, the server 8208, etc.), and performance of communication through an established communication channel. The communication module 8290 may operate independently from the processor 8220 (e.g., an application processor) and may include one or more communication processors that support direct communication and/or wireless communication. The communication module 8290 may include a wireless communication module 8292 (e.g., a cellular communication module, a short-range wireless communication module, Global Navigation Satellite System (GNSS) communication module), and/or a wired communication module 8294 (local area network (LAN) communication module), a power line communication module, etc.). The communication module 8290 may communicate with another electronic device via the first network 8298 (e.g., a short-range communication network such as Bluetooth, WiFi Direct, or Infrared Data Association (IrDA)) or the second network 8299 (e.g., a long-range communication network such as a cellular network, the Internet, or a computer network (LAN, wide area network (WAN), etc.)). Various types of communication modules as described above may be integrated into a single component (such as a single chip) or implemented as a plurality of separate components (a plurality of chips). The wireless communication module 8292 may identify and authenticate the electronic device 8201 within a communication network, such as the first network 8298 and/or the second network 8299, using subscriber information (such as international mobile subscriber identity (IMSI)) stored in the subscriber identification module 8296.

The antenna module 8297 may transmit signals and/or power to or receive signals and/or power from an external source (e.g., another electronic device). An antenna may include a radiator including a conductive pattern on a substrate (e.g., a printed circuit board (PCB)). The antenna module 8297 may include one or more antennas. When a plurality of antennas are included, an antenna suitable for a communication method used in a communication network, such as the first network 8298 and/or the second network 8299, may be selected from among the plurality of antennas by the communication module 8290. Signals and/or power may be transmitted or received between the communication module 8290 and another electronic device via a selected antenna. In addition to an antenna, other components (e.g., a radio frequency integrated circuit (RFIC)) may be included as a portion of the antenna module 8297.

Some of the components of the electronic device 8201 may be connected to each other and exchange signals (e.g., commands, data, etc.) through methods for communication between peripheral devices (e.g., bus, general purpose input and output (GPIO), serial peripheral interface (SPI), mobile industry processor interface (MIPI), etc.).

Commands or data may be transmitted or received between the electronic device 8201 and an external electronic device 8204 via the server 8208 connected to the second network 8299. Other electronic devices 8202 and 8204 may be the same or a different type of devices as the electronic device 8201. All or a part of operations executed on the electronic device 8201 may be executed on one or more of the other electronic devices 8202, 8204, and 8208. For example, when the electronic device 8201 needs to perform a function or a service, instead of executing the function or the service itself, the electronic device 8201 may request one or more other electronic devices to perform a part or all of the function or the service. One or more other electronic devices that receive the request may execute additional functions or services related to the request and transmit a result of the execution to the electronic device 8201. For this purpose, cloud computing, distributed computing, and/or client-server computing technologies may be utilized.

The electronic device 8201 may be applied to various devices. Depending on the function of a device, various components of the electronic device 8201 may be appropriately modified, and components appropriate for performing the function of the device may be added. Hereinafter, example applications of the electronic device 8201 are described.

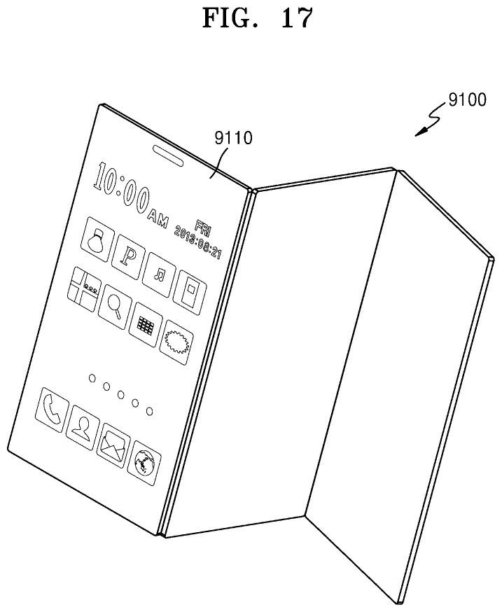

FIGS. 17 to 21 are diagrams illustrating example electronic devices including a light source or a display apparatus according to embodiments, respectively.

FIG. 17 is a drawing illustrating an example application of an electronic device including a light source or a display apparatus according to embodiments, which may include an embodiment of a mobile device. A mobile device 9100 may include a display apparatus 9110. The display apparatus 9110 may include at least one of light sources having various structures as exemplified in FIGS. 1 to 6 and display apparatuses having various structures as exemplified in FIGS. 9 to 14. The display apparatus 9110 may have a foldable structure, e.g., a multi-foldable structure.

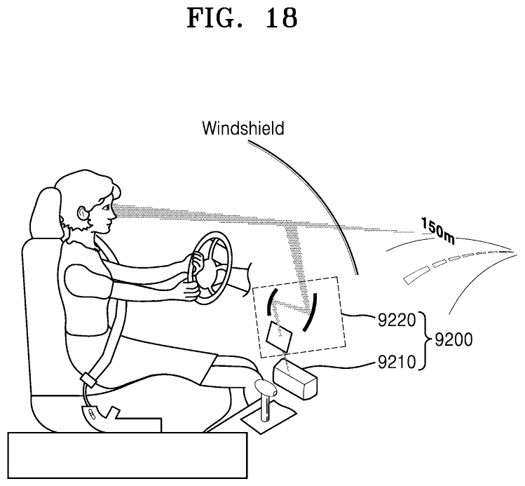

FIG. 18 is a drawing illustrating an example application of an electronic device including a light source or a display apparatus according to embodiments, which may include an embodiment of a head-up display apparatus for a vehicle. A head-up display apparatus 9200 for a vehicle may include a display 9210 provided in a region of a vehicle, and an optical path changing member 9220 that changes an optical path, such that a driver may view an image displayed on the display 9210. The display 9210 may include at least one of light sources having various structures as exemplified in FIGS. 1 to 6 and display apparatuses having various structures as exemplified in FIGS. 9 to 14.

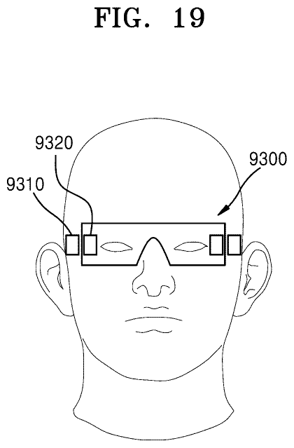

FIG. 19 is a drawing illustrating an example application of an electronic device including a light source or a display apparatus according to embodiments, which may include an embodiment of augmented reality glasses or virtual reality glasses. Augmented reality glasses (or virtual reality glasses) 9300 may include a projection system 9310 that forms an image and an element 9320 that guides the image from the projection system 9310 into a user's eyes. The projection system 9310 may include at least one of light sources having various structures as exemplified in FIGS. 1 to 6 and display apparatuses having various structures as exemplified in FIGS. 9 to 14.

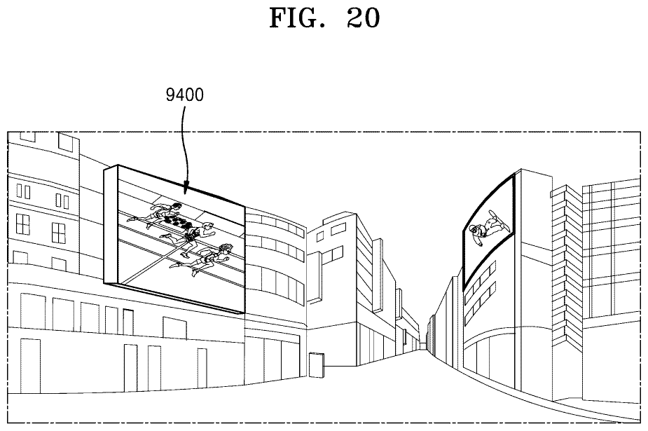

FIG. 20 is a drawing illustrating an example application of an electronic device including a light source or a display apparatus according to embodiments, which may include an embodiment of a large signage. A signage 9400 may include at least one of light sources having various structures as exemplified in FIGS. 1 to 6 and display apparatuses having various structures as exemplified in FIGS. 9 to 14. The signage 9400 may be used for outdoor advertisement using a digital information display, and advertising content, etc. and may be controlled through a communication network.

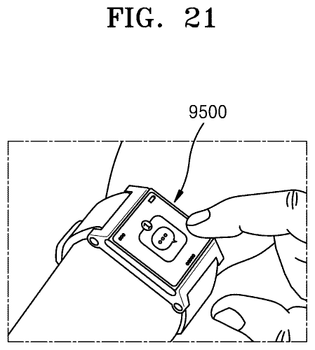

FIG. 21 is a drawing illustrating an example application of an electronic device including a light source or a display apparatus according to embodiments, which may include an embodiment of a wearable display. A wearable display 9500 may include at least one of light sources having various structures as exemplified in FIGS. 1 to 6 and display apparatuses having various structures as exemplified in FIGS. 9 to 14.

The light sources having various structures exemplified in FIGS. 1 to 6 and the display apparatuses having various structures exemplified in FIGS. 9 to 14 may also be applied to various products other than the above-stated electronic devices, e.g., a rollable television (TV), a stretchable display, etc.

While the disclosure has been particularly shown and described with reference to example embodiments thereof, it will be understood that various changes in form and details may be made therein without departing from the spirit and scope of the following claims.

What is claimed is:

1. A light source comprising:
a first conductive type base semiconductor layer;
a semiconductor light-emitting structure on a first surface of the first conductive type base semiconductor layer, the semiconductor light-emitting structure comprising a first conductive type semiconductor layer, an active layer, and a second conductive type semiconductor layer sequentially stacked in a vertical direction;
a reflective structure configured to surround sidewalls of the semiconductor light-emitting structure and penetrate through at least a portion of the first conductive type base semiconductor layer; and
a plurality of lenses arranged on a second surface of the first conductive type base semiconductor layer.

2. The light source of claim 1, wherein the reflective structure comprises a first portion extending in a horizontal direction and a second portion extending in the vertical direction from an end portion of the first portion.

3. The light source of claim 2, wherein one surface of the first portion of the reflective structure is coplanar with the second surface of the first conductive type base semiconductor layer.

4. The light source of claim 2, wherein at least a portion of one surface of the first portion of the reflective structure is in contact with at least a portion of the plurality of lenses.

5. The light source of claim 2, wherein a width of the first portion of the reflective structure in the horizontal direction is greater than a distance between the plurality of lenses.

6. The light source of claim 2, further comprising an insulation layer in a region surrounded by the first portion and the second portion of the reflective structure.

7. The light source of claim 2, wherein the second portion has a slope with respect to the vertical direction and extends in the vertical direction.

8. The light source of claim 1, wherein the reflective structure comprises a capping layer surrounding the sidewalls of the semiconductor light-emitting structure, and a first metal layer vertically overlapping the capping layer and having sidewalls surrounded by the first conductive type base semiconductor layer.

9. The light source of claim 8, wherein a horizontal width of the first conductive type semiconductor layer is less than a horizontal width of the second conductive type semiconductor layer.

10. The light source of claim 8, wherein the first metal layer is spaced apart from the semiconductor light-emitting structure in a horizontal direction and the vertical direction.

11. The light source of claim 8, wherein the reflective structure further comprises a second metal layer provided between sidewalls of the first metal layer and the first conductive type base semiconductor layer, and
wherein the second metal layer contacts the capping layer and at least a portion of the plurality of lenses.

12. The light source of claim 1, further comprising an insulation spacer configured to cover the sidewalls of the semiconductor light-emitting structure,
wherein the reflective structure is spaced apart from the semiconductor light-emitting structure with the insulation spacer therebetween.

13. A light source comprising:
a plurality of pixels, at least one pixel of which comprises a first conductive type base semiconductor layer and a semiconductor light-emitting structure on a first surface of the first conductive type base semiconductor layer, the semiconductor light-emitting structure comprising a first conductive type semiconductor layer, an active layer, and a second conductive type semiconductor layer sequentially stacked in a vertical direction;
a plurality of transparent electrode layers configured to cover second conductive type semiconductor layers, respectively and spaced vertically from active layers with the second conductive type semiconductor layers therebetween;
a plurality of reflective electrode layers in contact with the plurality of transparent electrode layers and spaced apart in the vertical direction from the second conductive type semiconductor layers with the plurality of transparent electrode layers therebetween, respectively; and
a reflective structure configured to surround sidewalls of the semiconductor light-emitting structure and have at least a portion overlapping the first conductive type base semiconductor layer in a horizontal direction,
wherein the reflective structure comprises a first portion extending in the horizontal direction and a second portion having an inclination and extending in the vertical direction from an end portion of the first portion.

14. The light source of claim 13, further comprising an insulation layer in a region surrounded by the first portion and the second portion of the reflective structure.

15. The light source of claim 13, further comprising a plurality of lenses having surfaces facing a second surface of the first conductive type base semiconductor layer and configured to extract a light emitted from the semiconductor light-emitting structure, the first surface and the second surface of the first conductive type base semiconductor layer being opposite to each other,
wherein at least a portion of the first portion of the reflective structure overlaps at least a portion of the plurality of lenses in the vertical direction.

16. The light source of claim 13, further comprising an insulation spacer configured to cover the sidewalls of the semiconductor light-emitting structure,
wherein the reflective structure is spaced apart from the semiconductor light-emitting structure with the insulation spacer therebetween.

17. The light source of claim 13, wherein the reflective structure comprises a capping layer surrounding the sidewalls of the semiconductor light-emitting structure and a first metal layer penetrating through at least a portion of the first conductive type base semiconductor layer.

18. The light source of claim 17, wherein the reflective structure further comprises a second metal layer disposed on sidewalls of the first metal layer, and
wherein the first metal layer and the second metal layer overlap the capping layer in the vertical direction.

19. A display apparatus comprising:
a circuit board comprising a driving circuit;
a pixel array comprising a plurality of pixels arranged on the circuit board and comprising semiconductor light-emitting structures;
a plurality of lenses respectively disposed over the plurality of pixels; and
a reflective structure configured to surround each of the plurality of pixels and contact at least a portion of the plurality of lenses,
wherein at least one pixel of the plurality of pixels comprises a first conductive type base semiconductor layer and a semiconductor light-emitting structure, the semiconductor light-emitting structure comprising a first conductive type semiconductor layer, an active layer, and a second conductive type semiconductor layer sequentially stacked in a vertical direction,
wherein the semiconductor light-emitting structure is spaced apart from one lens selected from among the plurality of lenses with the first conductive type base semiconductor layer therebetween, and
wherein the reflective structure comprises a first portion extending in a horizontal direction and a second portion having an inclination and extending in the vertical direction from an end portion of the first portion.

20. The display apparatus of claim 19, further comprising:
an insulation spacer disposed between the semiconductor light-emitting structure and the reflective structure; and
an insulation layer in a region surrounded by the first portion and the second portion of the reflective structure,
wherein each of the insulation spacer and the insulation layer is in contact with the reflective structure.
